(19) United States
(12) Patent Application Publication
(10) Pub. No.: US 2024/0105835 A1
(43) Pub. Date: Mar. 28, 2024

(54) SEMICONDUCTOR DEVICE

(71) Applicant: ROHM CO., LTD., Kyoto-shi (JP)

(72) Inventor: Tomoaki SHINODA, Kyoto-shi (JP)

(73) Assignee: ROHM CO., LTD., Kyoto-shi (JP)

(21) Appl. No.: 18/536,248

(22) Filed: Dec. 12, 2023

Related U.S. Application Data
(63) Continuation of application No. PCT/JP2022/018821, filed on Apr. 26, 2022.

(30) Foreign Application Priority Data
Jun. 14, 2021 (JP) 2021-098851

(51) Int. Cl. H01L 29/78; H01L 23/528; H01L 29/40; H01L 29/417

(52) U.S. Cl. CPC H01L 29/7813; H01L 23/528; H01L 29/407; H01L 29/41741

(57) ABSTRACT

A semiconductor device is provided with: a plurality of gate trenches; a plurality of gate electrodes; a plurality of field plate electrodes; gate wiring that is connected to each gate electrode and forms a loop in plan view; first source wiring that is connected to a first end of each field plate electrode and is disposed within the loop of the gate wiring in plan view; second source wiring that is connected to a second end of each field plate electrode and is disposed outside the loop of the gate wiring in plan view; and, a connection structure. The connection structure includes a connection trench that intersects the gate wiring in plan view, and inter-source wiring embedded in the connection trench. The inter-source wiring electrically connects the first source wiring and the second source wiring.

### CROSS-REFERENCE TO RELATED APPLICATIONS

The present application is a bypass continuation of International Patent Application No. PCT/JP2022/018821, filed on Apr. 26, 2022, which corresponds to Japanese Patent Application No. 2021-098851 filed on Jun. 14, 2021, with the Japan Patent Office, and the entire disclosure of these applications are incorporated herein by reference.

### BACKGROUND

### 1. Field

The present disclosure relates to a semiconductor device.

### 2. Description of Related Art

Japanese Laid-Open Patent Publication No. 2018-129378 discloses a metal insulator semiconductor field effect transistor (MISFET) having a split-gate structure.

The split-gate structure disclosed in Japanese Laid-Open Patent Publication No. 2018-129378 includes a gate trench formed in a semiconductor layer, an embedded electrode embedded in the bottom of the gate trench as a field plate electrode, a gate electrode formed in an upper portion of the gate trench, and an insulation layer separating the two electrodes in the gate trench. The semiconductor layer disclosed in Japanese Laid-Open Patent Publication No. 2018-129378 includes an n⁺-type source region, a p-type body region, and an n⁻-type drift region.

### BRIEF DESCRIPTION OF THE DRAWINGS

FIG. 1 is a schematic plan view showing an exemplary semiconductor device in an embodiment.

FIG. 2 is a schematic cross-sectional view of the semiconductor device taken along line F2-F2 in FIG. 1.

FIG. 3 is a schematic cross-sectional view of the semiconductor device taken along line F3-F3 in FIG. 1.

FIG. 4 is a schematic cross-sectional view of the semiconductor device taken along line F4-F4 in FIG. 1.

FIG. 5 is a schematic cross-sectional view of the semiconductor device taken along line F5-F5 in FIG. 1.

FIG. 6 is a schematic plan view of a semiconductor device in a first example.

FIG. 7 is a schematic plan view of a semiconductor device in a second example.

FIG. 8 is a schematic cross-sectional view of the semiconductor device taken along line F8-F8 in FIG. 7.

FIG. 9 is a graph showing resistance Rₛ in first to third examples.

FIG. 10 is a schematic cross-sectional view showing an exemplary semiconductor device in a first modified example.

FIG. 11 is a schematic cross-sectional view showing an exemplary semiconductor device in a second modified example.

FIG. 12 is a schematic cross-sectional view showing an exemplary semiconductor device in a third modified example.

FIG. 13 is a schematic cross-sectional view showing an exemplary semiconductor device in a fourth modified example.

### DETAILED DESCRIPTION

Embodiments of a semiconductor device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

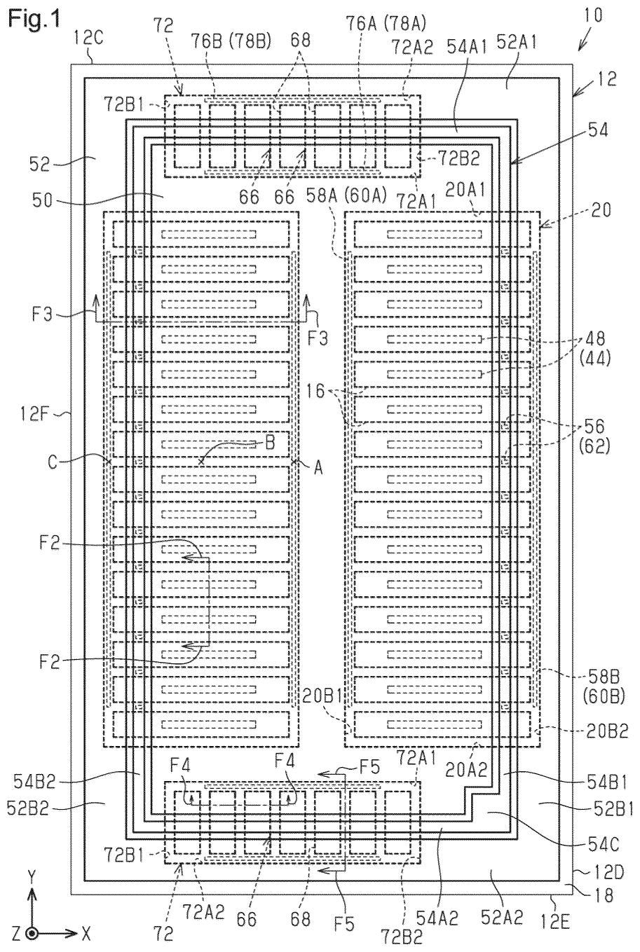

FIG. 1 is a schematic plan view showing an exemplary semiconductor device 10 in an embodiment. The term “plan view” used in the present disclosure refers to a view of the semiconductor device 10 in the Z-direction when the XYZ-axes are orthogonal to each other as shown in FIG. 1.

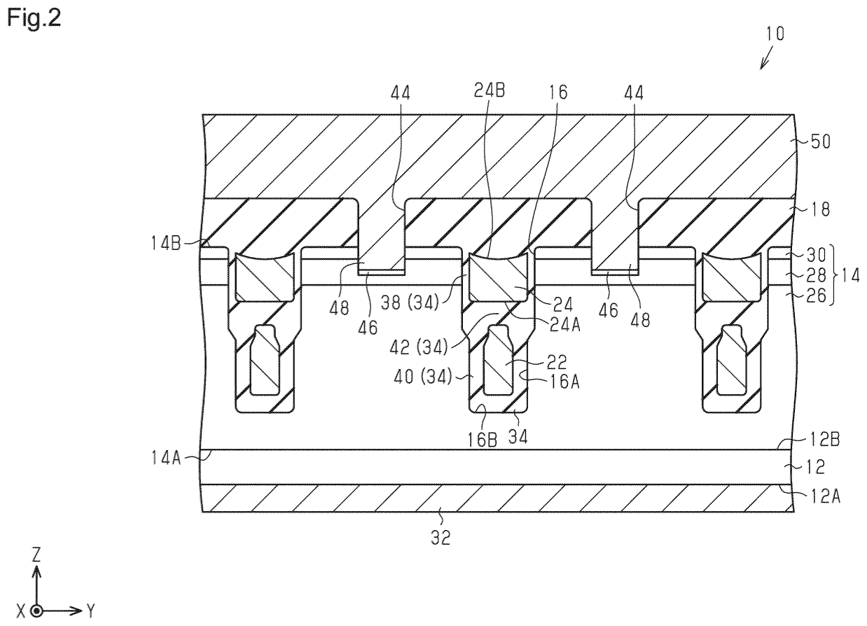

The semiconductor device 10 is, for example, a MISFET having a split-gate structure. The semiconductor device 10 may include a semiconductor substrate 12. The semiconductor substrate 12 may be a Si substrate. The semiconductor substrate 12 includes a bottom surface 12A and an upper surface 12B opposite to the bottom surface 12A, which will be described later with reference to FIG. 2. In FIG. 1, the Z-direction is orthogonal to the bottom surface 12A and the upper surface 12B of the semiconductor substrate 12.

The semiconductor device 10 may further include a semiconductor layer 14 including a first surface 14A and a second surface 14B opposite to the first surface 14A, gate trenches 16 formed in the second surface 14B of the semiconductor layer 14, and an insulation layer 18 formed on the second surface 14B of the semiconductor layer 14. The semiconductor layer 14 is covered by the insulation layer 18 and thus is not shown in FIG. 1. As shown in FIG. 2, which will be used later in the description, the semiconductor layer 14 is formed on the upper surface 12B of the semiconductor substrate 12. Thus, the upper surface 12B of the semiconductor substrate 12 is located adjacent to the first surface 14A of the semiconductor layer 14.

In the example shown in FIG. 1, the upper surface 12B of the semiconductor substrate 12 includes two sides 12C and 12E extending in the X-direction and two sides 12D and 12F extending in the Y-direction. The upper surface 12B of the semiconductor substrate 12 is covered by the semiconductor layer 14 and the insulation layer 18. In FIG. 1, only the rectangular edges (i.e., four sides 12C, 12D, 12E, and 12F) of the semiconductor substrate 12 are shown. In FIG. 1, the region defined by the edges of the semiconductor substrate 12 may correspond to one chip (die). In the present disclosure, the X-direction may also be referred to as a first direction, and the Y-direction may also be referred to as a second direction. Therefore, the first direction and the second direction are parallel to the second surface 14B of the semiconductor layer 14. The second direction is orthogonal to the first direction. In the example shown in FIG. 1, the sides 12C and 12E, which extend in the X-direction, are equal in length to each other and are shorter than the sides 12D and 12F, which extend in the Y-direction. The sides 12D and 12F, which extend in the Y-direction, are equal in length to each other and are longer than the sides 12C and 12E, which extend in the X-direction. In other words, the longitudinal direction and the lateral direction of the upper surface 12B of the semiconductor substrate 12 correspond to the Y-direction and the X-direction, respectively. In another example, the sides 12C and 12E may be equal in length to the sides 12D and 12F or may be longer than the sides 12D and 12F.

The semiconductor layer 14 may be formed of a Si epitaxial layer. The semiconductor layer 14 may be identical in shape to the semiconductor substrate 12 in plan view. The detail of the semiconductor layer 14 will be described later with reference to FIG. 2.

The insulation layer 18 may include at least one of a silicon oxide (SiO₂) layer and a silicon nitride (SiN) layer. The insulation layer 18 may also be referred to as an inter-layer insulation film (inter-layer dielectric: ILD).

In FIG. 1, the gate trenches 16 are shown by broken lines. At least some of the gate trenches 16 may be equidistantly arranged parallel to each other. In the example shown in FIG. 1, the gate trenches 16 extend in the X-direction in plan view. Alternatively, groups of the gate trenches 16 may be formed in the semiconductor layer 14. Each group may include gate trenches 16 that are equidistantly arranged parallel to each other. In the example shown in FIG. 1, two groups of gate trenches 16 equidistantly arranged parallel to each other are formed in the semiconductor layer 14. One of the groups of the gate trenches 16 is disposed to intersect a third gate interconnect part 54B1 in plan view, which will be described later. The other group of the gate trenches 16 is disposed to intersect a fourth gate interconnect part 54B2 in plan view, which will be described later.

The semiconductor device 10 may further include a peripheral trench 20 formed in the second surface 14B of the semiconductor layer 14. The peripheral trench 20 may surround the gate trenches 16 in plan view and be connected to each of the gate trenches 16. More specifically, the peripheral trench 20 may include two trench parts 20A1 and 20A2 parallel to the gate trenches 16 and two trench parts 20B1 and 20B2 connected to the gate trenches 16. The two trench parts 20A1 and 20A2 and the two trench parts 20B1 and 20B2 may be connected to each other so that the peripheral trench 20 surrounds the gate trenches 16. In the example shown in FIG. 1, the trench part 20A1, the gate trenches 16, and the trench part 20A2 are arranged in this order in the Y-direction. In other words, the gate trenches 16 are located between the two trench parts 20A1 and 20A2.

In another example, the peripheral trench 20 may include only the two trench parts 20A1 and 20A2, which are parallel to the gate trenches 16, or may include only the two trench parts 20B1 and 20B2, which are connected to the gate trenches 16. Alternatively, the peripheral trench 20 may be omitted.

In each of the gate trenches 16, a field plate electrode 22 and a gate electrode 24 are embedded and will be described with reference to FIG. 2.

FIG. 2 is a schematic cross-sectional view of the semiconductor device 10 taken along line F2-F2 in FIG. 1. FIG. 2 shows a cross section of three gate trenches 16 in the YZ-plane. Although a single gate trench 16 and its related structures will be described below, the description will apply to each of the gate trenches 16 and its related structures.

The semiconductor substrate 12 corresponds to a drain region of the MISFET. The semiconductor layer 14 includes a drift region 26 formed on the semiconductor substrate 12 (drain region), a body region 28 formed on the drift region 26, and a source region 30 formed on the body region 28.

The drain region of the semiconductor substrate 12 is an n-type region including an n-type impurity. The concentration of the n-type impurity in the semiconductor substrate 12 may be in a range of 1×10¹⁸ cm⁻³ to 1×10²⁰ cm⁻³. The semiconductor substrate 12 may have a thickness in a range of 40 μm and 450 μm.

The drift region 26 is an n-type region including an n-type impurity at a lower concentration than the semiconductor substrate 12 (drain region). The concentration of the n-type impurity in the drift region 26 may be in a range of 1×10¹⁵ cm⁻³ to 1×10¹⁸ cm⁻³. The drift region 26 may have a thickness in a range of 1 μm to 25 μm.

The body region 28 is a p-type region including a p-type impurity. The concentration of the p-type impurity in the body region 28 may be in a range of 1×10¹⁶ cm⁻³ to 1×10¹⁸ cm⁻³. The body region 28 may have a thickness in a range of 0.5 μm to 1.5 μm.

The source region 30 is an n-type region including an n-type impurity at a higher concentration than the drift region 26. The concentration of the n-type impurity in the source region 30 may be in a range of 1×10¹⁹ cm⁻³ to 1×10²¹ cm⁻³. The source region 30 may have a thickness in a range of 0.1 μm to 1 μm.

In the present disclosure, n-type is also referred to as a first conductive type, and p-type is also referred to as a second conductive type. The n-type impurity may include, for example, at least one of phosphorus (P) and arsenic (As). The p-type impurity may include, for example, at least one of boron (B) and aluminum (Al).

The semiconductor device 10 may further include a drain electrode 32 formed on the bottom surface 12A of the semiconductor substrate 12. The drain electrode 32 is electrically connected to the semiconductor substrate 12 (drain region). The drain electrode 32 may be formed from at least one of titanium (Ti), nickel (Ni), gold (Au), silver (Ag), copper (Cu), Al, a Cu alloy, and an Al alloy.

The gate trench 16 is formed in the second surface 14B of the semiconductor layer 14. The gate trench 16 includes a side wall 16A and a bottom wall 16B. The gate trench 16 extends through the source region 30 and the body region 28 of the semiconductor layer 14 and reaches the drift region 26. Thus, the bottom wall 16B of the gate trench 16 is located adjacent to the drift region 26. The gate trench 16 may have a depth in a range of 1 μm to 15 μm.

The field plate electrode 22 and the gate electrode 24 are formed in the gate trench 16. The field plate electrode 22 and the gate electrode 24 are separated from each other by a trench insulation layer 34. The trench insulation layer 34 covers the side wall 16A and the bottom wall 16B of the gate trench 16. The gate electrode 24 is disposed above the field plate electrode 22 in the gate trench 16. The structure in which two separated electrodes are embedded in a gate trench as described above may be referred to as a split-gate structure.

The field plate electrode 22 is located in the gate trench 16 between the bottom wall 16B of the gate trench 16 and a bottom surface 24A of the gate electrode 24. The field plate electrode 22 is surrounded by the trench insulation layer 34. Application of the source voltage to the field plate electrode 22 will reduce concentration of electric field in the gate trench 16 and improve the breakdown voltage of the semiconductor device 10. Thus, the field plate electrode 22 and the source region 30 have the same potential.

The gate electrode 24 includes a bottom surface 24A at least partially opposed to the field plate electrode 22. The gate electrode 24 also includes an upper surface 24B opposite to the bottom surface 24A. The upper surface 24B of the gate electrode 24 may be located below the second surface 14B of the semiconductor layer 14.

In an example, the field plate electrode 22 and the gate electrode 24 are formed from a conductive polysilicon.

The trench insulation layer 34 includes a gate insulator 38 disposed between the gate electrode 24 and the semiconductor layer 14 and covering the side wall 16A of the gate trench 16. The gate electrode 24 and the semiconductor layer 14 are separated by the gate insulator 38 in the Y-direction. When a predetermined voltage is applied to the gate electrode 24, a channel is formed in the p-type body region 28, which is located adjacent to the gate insulator 38. The semiconductor device 10 controls the flow of electrons through the channel in the Z-direction between the n-type source region 30 and the n-type drift region 26.

The trench insulation layer 34 may further include a lower insulator 40 and an intermediate insulator 42. The lower insulator 40 covers the side wall 16A and the bottom wall 16B of the gate trench 16 between the field plate electrode 22 and the semiconductor layer 14. The intermediate insulator 42 is located between the field plate electrode 22 and the gate electrode 24 in the depth-wise direction of the gate trench 16. The lower insulator 40 may be greater in thickness than the gate insulator 38 on the side wall 16A of the gate trench 16. In an example, the trench insulation layer 34 may be formed from SiO₂.

The insulation layer 18 is formed on the second surface 14B of the semiconductor layer 14 and covers the gate electrode 24 and the trench insulation layer 34 embedded in the gate trench 16. The insulation layer 18 may include a cap insulation layer (not shown) covering the upper surface 24B of the gate electrode 24.

The insulation layer 18 includes a contact trench 44 and a contact region 46 located adjacent to the bottom wall of the contact trench 44. The contact trench 44 extends through the insulation layer 18 and the source region 30 and reaches the body region 28. The contact region 46 is a p-type region including a p-type impurity. The concentration of the p-type impurity in the contact region 46 may be higher than that of the body region 28 and in a range of 1×10¹⁹ cm⁻³ to 1×10²¹ cm⁻³. A source contact 48 is embedded in the contact trench 44. In plan view, the contact trench 44 extends parallel to the gate trench 16 (in the example shown in FIGS. 1 and 2, in the X-direction). Accordingly, the source contact 48 may also extend parallel to the gate trench 16 in plan view (refer to FIG. 1). Each gate trench 16 is located between two source contacts 48 in plan view. The source contacts 48 are connected to a first source interconnect 50 formed on the insulation layer 18. Thus, the contact region 46 is electrically connected to the first source interconnect 50 by the source contacts 48.

As shown in FIG. 1, the semiconductor device 10 includes multiple gate trenches 16. Thus, the semiconductor device 10 may include (multiple) field plate electrodes 22 that are equal in number to the gate trenches 16 and (multiple) gate electrodes 24 that are equal in number to the gate trenches 16. In other words, each of the field plate electrodes 22 is embedded in a corresponding one of the gate trenches 16. In the same manner, each of the gate electrodes 24 is embedded in a corresponding one of the gate trenches 16. One of the field plate electrodes 22 is insulated from one of the gate electrodes 24 and is embedded in the corresponding one of the gate trenches 16.

The first source interconnect 50, a second source interconnect 52, and a gate interconnect 54, which are formed on the insulation layer 18, will be described with reference to FIG. 1.

The semiconductor device 10 may further include the gate interconnect 54 formed on the insulation layer 18. The gate interconnect 54 is connected to each of the gate electrodes 24 and form a loop in plan view. In particular, in the present embodiment, the gate interconnect 54 forms a closed loop in plan view. Each gate electrode 24 may be connected to the gate interconnect 54 by a gate contact 56 formed on the insulation layer 18.

The gate interconnect 54 may include a first gate interconnect part 54A1 and a second gate interconnect part 54A2 extending in the X-direction and the third gate interconnect part 54B1 and the fourth gate interconnect part 54B2 extending in the Y-direction. In the example shown in FIG. 1, the first gate interconnect part 54A1 is located toward the side 12C of the semiconductor substrate 12. The second gate interconnect part 54A2 is located toward the side 12E of the semiconductor substrate 12. The third gate interconnect part 54B1 is located toward the side 12D of the semiconductor substrate 12. The fourth gate interconnect part 54B2 is located toward the side 12F of the semiconductor substrate 12. The first gate interconnect part 54A1 is connected to one end of the third gate interconnect part 54B1 and one end of the fourth gate interconnect part 54B2, and the second gate interconnect part 54A2 is connected to the other end of the third gate interconnect part 54B1 and the other end of the fourth gate interconnect part 54B2 so that the gate interconnect 54 forms a rectangular closed loop in plan view. The gate interconnect 54 may further include a gate pad 54C. In the example shown in FIG. 1, the gate pad 54C is located at a corner of the loop connecting the second gate interconnect part 54A2 and the third gate interconnect part 54B1.

The semiconductor device 10 may further include the first source interconnect 50 formed on the insulation layer 18 and the second source interconnect 52 formed on the insulation layer 18. The first source interconnect 50 is disposed inside the loop of the gate interconnect 54 in plan view. The second source interconnect 52 is disposed outside the loop of the gate interconnect 54 in plan view.

The first source interconnect 50 and the second source interconnect 52 are insulated from the gate interconnect 54. In an example, inter-metal dielectrics (TIMD) may be arranged to separate the first source interconnect 50 and the second source interconnect 52 from the gate interconnect 54. For the sake of simplicity, FIG. 1 does not show the inter-metal dielectrics.

The structure for insulating the first source interconnect 50 and the second source interconnect 52 from the gate interconnect 54 is not limited to that described above. In an example, the semiconductor device 10 may include an insulation layer coating each of the interconnects 50, 52, and 54. In this case, the insulation layer may include a portion coating the first source interconnect 50, a portion coating the second source interconnect 52, and a portion coating the gate interconnect 54, and an insulative resin may fill the space between the coating portions.

The first source interconnect 50 is surrounded by the gate interconnect 54 in plan view. The first source interconnect 50 may be arranged so that the first source interconnect 50 is separated from the gate interconnect 54 by an appropriate distance determined taking into consideration breakdown voltage and the like. The first source interconnect 50 may cover an active region of the semiconductor layer 14. The active region refers to a region in which a main part of the MISFET, that is, a part contributing to the operation of a transistor, is formed.

The second source interconnect 52 surrounds the gate interconnect 54 in plan view. The second source interconnect 52 may be arranged so that the second source interconnect 52 is separated from the gate interconnect 54 by an appropriate distance determined taking into consideration breakdown voltage and the like. The second source interconnect 52 may include source fingers 52A1 and 52A2 extending in the X-direction in plan view and source fingers 52B1 and 52B2 extending in the Y-direction in plan view. The source finger 52A1 is located toward the side 12C of the semiconductor substrate 12. The source finger 52A1 may be at least partially located between the side 12C of the semiconductor substrate 12 and the first gate interconnect part 54A1 in plan view. The source finger 52A2 is located toward the side 12E of the semiconductor substrate 12. The source finger 52A2 may be at least partially located between the side 12E of the semiconductor substrate 12 and the second gate interconnect part 54A2 in plan view. The source finger 52B1 is located toward the side 12D of the semiconductor substrate 12. The source finger 52B1 may be at least partially located between the side 12D of the semiconductor substrate 12 and the third gate interconnect part 54B1 in plan view. The source finger 52B2 is located toward the side 12F of the semiconductor substrate 12. The source finger 52B2 may be at least partially located between the side 12F of the semiconductor substrate 12 and the fourth gate interconnect part 54B2 in plan view.

In the example shown in FIG. 1, the source finger 52A1 is connected to one end of the source finger 52B1 and one end of the source finger 52B2, and the source finger 52A2 is connected to the other end of the source finger 52B1 and the other end of the source finger 52B2. As described above, the second source interconnect 52 may form a rectangular closed loop in plan view. In another example, the second source interconnect 52 may form an open loop. Each of the source fingers 52A1, 52A2, 52B1, and 52B2 may be connected to at least one of the other source fingers 52A1, 52A2, 52B1, and 52B2.

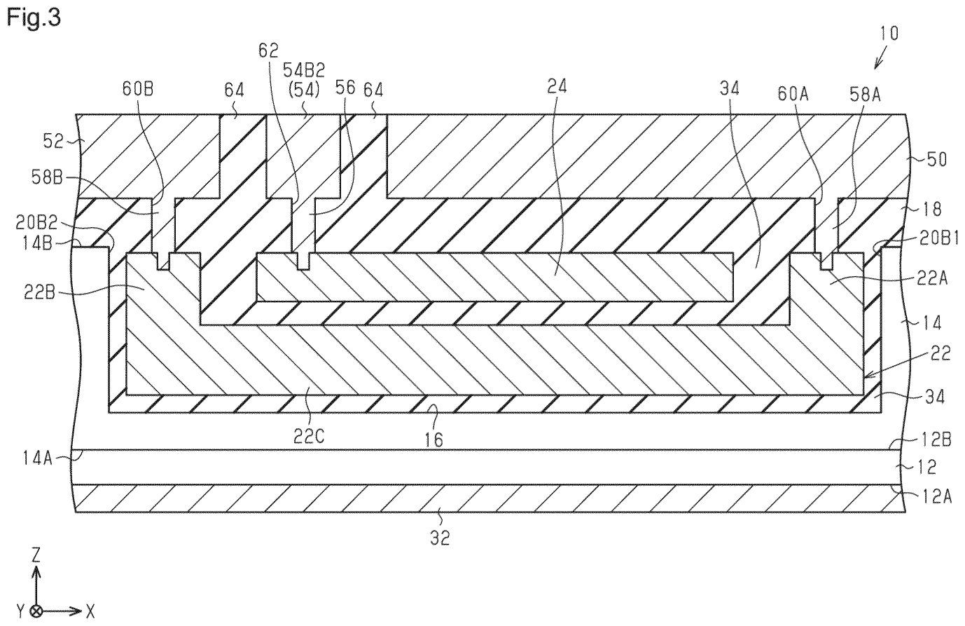

The gate trenches 16 may be arranged to at least partially overlap all of the first source interconnect 50, the second source interconnect 52, and the gate interconnect 54 in plan view. Each of the gate trenches 16 is arranged to intersect the gate interconnect 54 in plan view, and the gate electrode 24 embedded in the gate trench 16 is connected to the gate interconnect 54 by the gate contact 56. The first source interconnect 50 is connected to a first end 22A of each field plate electrode 22. The second source interconnect 52 is connected to a second end 22B of each field plate electrode 22. The first end 22A and the second end 22B of the field plate electrode 22 will be described later with reference to FIG. 3.

In the example shown in FIG. 1, the third gate interconnect part 54B1 and the fourth gate interconnect part 54B2 each intersect with the peripheral trench 20 and the gate trenches 16 surrounded by the peripheral trench 20. In another example, the first gate interconnect part 54A1 and the second gate interconnect part 54A2 may each intersect with the peripheral trench 20 and the gate trenches 16 surrounded by the peripheral trench 20. Alternatively, only one of the first gate interconnect part 54A1, the second gate interconnect part 54A2, the third gate interconnect part 54B1, and the fourth gate interconnect part 54B2 may intersect with the peripheral trench 20 and the gate trenches 16 surrounded by the peripheral trench 20.

FIG. 3 is a schematic cross-sectional view of the semiconductor device 10 taken along line F3-F3 in FIG. 1 showing a cross section of a gate trench 16 formed in the semiconductor layer 14 along the XZ-plane.

The field plate electrode 22 and the gate electrode 24 are embedded in the gate trench 16. The gate electrode 24 is arranged above the field plate electrode 22. The field plate electrode 22 includes the first end 22A connected to the first source interconnect 50 and the second end 22B connected to the second source interconnect 52. The gate trench 16 includes two ends connected to the trench parts 20B1 and 20B2 of the peripheral trench 20 extending in the Y-direction (refer to FIG. 1). Thus, the first end 22A and the second end 22B of the field plate electrode 22 are located in the trench parts 20B1 and 20B2 of the peripheral trench 20 extending in the Y-direction. The first end 22A and the second end 22B of the field plate electrode 22 extend in the Z-direction from the bottom to the opening of the peripheral trench 20. The field plate electrode 22 further includes an intermediate portion 22C extending between the first end 22A and the second end 22B. The intermediate portion 22C extends in a direction in which the gate trench 16 extends (in the example shown in FIG. 3, the X-direction). The intermediate portion 22C has a thickness that is smaller than that of the first end 22A and the second end 22B in a direction (the Z-direction) orthogonal to the second surface 14B of the semiconductor layer 14. The gate electrode 24 is located over the first end 22A and the second end 22B of the field plate electrode 22. The gate electrode 24 is located over the intermediate portion 22C of the field plate electrode 22 and, in plan view, located between the first end 22A and the second end 22B of the field plate electrode 22.

The field plate electrode 22 is connected to the first source interconnect 50 and the second source interconnect 52 by two field plate contacts 58A and 58B. The field plate contacts 58A and 58B may be embedded in contact trenches 60A and 60B formed in the insulation layer 18. The contact trenches 60A and 60B are formed to overlap the trench parts 20B1 and 20B2 of the peripheral trench 20 in plan view. In plan view, the contact trenches 60A and 60B each have a smaller area than the trench part 20B1 or 20B2. In this case, the field plate electrodes 22, which are embedded in the gate trenches 16, are connected to each other in the peripheral trench 20. In an example, a conductive joint may be arranged in the trench part 20B1 of the peripheral trench 20 to connect the first end 22A of each field plate electrode 22 to the first end 22A of an adjacent field plate electrode 22. In the same manner, a conductive joint may be arranged in the trench part 20B2 of the peripheral trench 20 to connect the second end 22B of each field plate electrode 22 to the second end 22B of an adjacent field plate electrode 22. In other words, the semiconductor device 10 may further include a conductive joint arranged in the peripheral trench 20 so that the conductive joint joins the field plate electrodes 22 to each other. The conductive joint may be formed from a conductive polysilicon in the same manner as the field plate electrodes 22. Thus, the field plate electrodes 22 may be formed integrally from the conductive polysilicon. In an example in which the peripheral trench 20 does not include the two trench parts 20B1 and 20B2 connected to the gate trenches 16, the field plate electrodes 22 may be separately formed in the semiconductor layer 14. In this case, each field plate electrode 22 may be connected to the first source interconnect 50 and the second source interconnect 52 by contacts embedded in vias formed in the insulation layer 18.

The gate electrode 24, which is embedded in the gate trench 16, is connected to the gate interconnect 54. More specifically, the gate electrode 24 is connected to the gate interconnect 54 by the gate contact 56, which extends through the insulation layer 18. While the field plate electrode 22 is connected to the first source interconnect 50 and the second source interconnect 52 by the two field plate contacts 58A and 58B, the gate electrode 24 is connected to the gate interconnect 54 by one gate contact 56. In the example shown in FIG. 3, the gate interconnect 54 that is connected to the gate electrode 24 is the fourth gate interconnect part 54B2. The gate contact 56 is embedded in a contact via 62 formed in the insulation layer 18. One gate contact 56 may be arranged for the gate electrode 24 located in each gate trench 16. Hence, the semiconductor device 10 may include the same number of the gate contacts 56 as the number of the gate trenches 16.

An insulation layer 64 is formed between the first source interconnect 50 and the gate interconnect 54 and between the gate interconnect 54 and the second source interconnect 52. The insulation layer 64 corresponds to an IMD insulating the interconnects from each other.

The insulation layer 64 fills the entire space between the first source interconnect 50 and the gate interconnect 54. However, there is no limit to such a structure. In an example, the insulation layer 64 located between the first source interconnect 50 and the gate interconnect 54 may be recessed in the center while covering the side surface of the first source interconnect 50 and the side surface of the gate interconnect 54. In this case, the recessed part of the insulation layer 64 may be filled with a resin. The same applies to the insulation layer 64 located between the gate interconnect 54 and the second source interconnect 52.

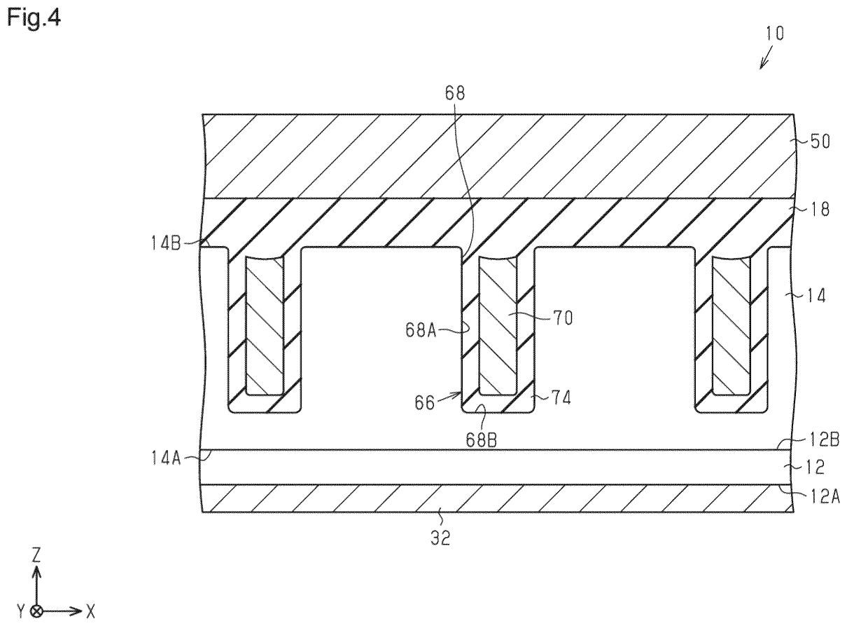

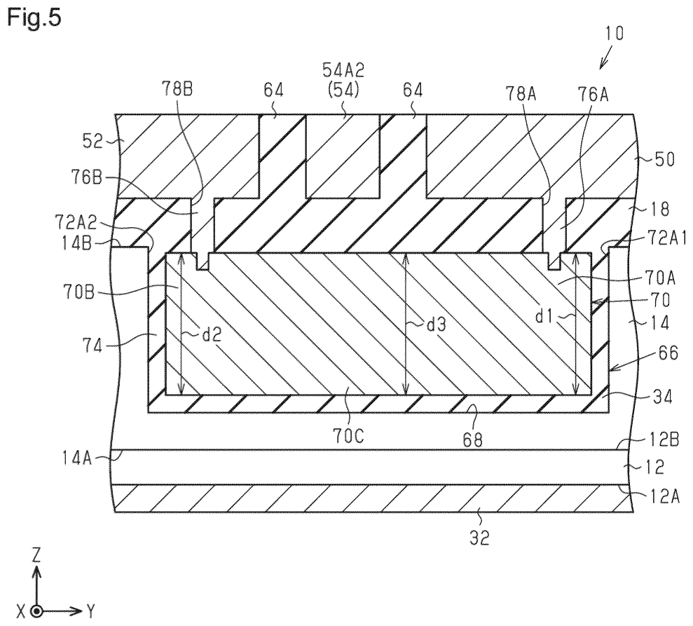

The first source interconnect 50 and the second source interconnect 52 are connected by a connection structure 66, which will be described with reference to FIG. 1. The semiconductor device 10 may further include a connection structure 66 formed in the semiconductor layer 14. The connection structure 66 includes a connection trench 68 and an inter-source interconnect 70 embedded in the connection trench 68. The inter-source interconnect 70 will be described later with reference to FIGS. 4 and 5.

The connection trench 68 is formed in the second surface 14B of the semiconductor layer 14 and intersects the gate interconnect 54 in plan view. In FIG. 1, the connection trenches 68 are indicated by broken lines. As in the example shown in FIG. 1, the connection structure 66 may be one of multiple connection structures 66. That is, the semiconductor device 10 may include multiple connection structures 66. In this case, the connection structures 66 may have the same structure. At least some of the connection structures 66 may be equidistantly arranged parallel to each other. In the example shown in FIG. 1, each of the connection structures 66 extends in the Y-direction in plan view. Alternatively, groups of the connection structures 66 may be formed in the semiconductor layer 14. Each group may include connection structures 66 that are equidistantly arranged parallel to each other. In the example shown in FIG. 1, two groups of the connection structures 66 equidistantly arranged parallel to each other are formed in the semiconductor layer 14. One of the groups of the connection structures 66 is disposed to intersect the first gate interconnect part 54A1 in plan view. The other group of the connection structures 66 is disposed to intersect the second gate interconnect part 54A2 in plan view.

The semiconductor device 10 may further include a peripheral trench 72 formed in the second surface 14B of the semiconductor layer 14. The peripheral trench 72 may surround the connection structures 66 in plan view and be connected to the connection trench 68 of each connection structure 66. More specifically, the peripheral trench 72 may include two trench parts 72A1 and 72A2 connected to the connection trenches 68 and two trench parts 72B1 and 72B2 parallel to the connection trenches 68. The two trench parts 72A1 and 72A2 and the two trench parts 72B1 and 72B2 may be connected to each other so that the peripheral trench 72 surrounds the connection trenches 68. In the example shown in FIG. 1, the trench part 72B1, the connection trenches 68, and the trench part 72B2 are arranged in this order in the X-direction. In other words, the connection trenches 68 are arranged between the two trench parts 72B1 and 72B2.

In another example, the peripheral trench 72 may include only the two trench parts 72A1 and 72A2, which are connected to the connection trenches 68, or may include only the two trench parts 72B1 and 72B2, which are parallel to the connection trenches 68. Alternatively, the peripheral trench 72 may be omitted.

In the example shown in FIG. 1, the first gate interconnect part 54A1 and the second gate interconnect part 54A2 each intersect with the peripheral trench 72 and the connection trenches 68 surrounded by the peripheral trench 72. In another example, the third gate interconnect part 54B1 and the fourth gate interconnect part 54B2 may each intersect with the peripheral trench 72 and the connection trenches 68 surrounded by the peripheral trench 72. Alternatively, only one of the first gate interconnect part 54A1, the second gate interconnect part 54A2, the third gate interconnect part 54B1, and the fourth gate interconnect part 54B2 may intersect with the peripheral trench 72 and the connection trenches 68 surrounded by the peripheral trench 72.

The connection structure 66 will be described further in detail with reference to the schematic cross-sectional views shown in FIGS. 4 and 5.

FIG. 4 is a schematic cross-sectional view of the semiconductor device 10 taken along line F4-F4 in FIG. 1. FIG. 4 shows a cross section of three connection trenches 68 in the XZ plane. As shown in FIG. 4, each connection structure 66 includes the connection trench 68 formed in the second surface 14B of the semiconductor layer 14 and the inter-source interconnect 70 embedded in the connection trench 68. In an example, the inter-source interconnect 70 may be formed from a conductive polysilicon. The inter-source interconnect 70 and the field plate electrode 22 may be formed from the same material.

The connection structure 66 further includes a trench insulation layer 74 covering a side wall 68A and a bottom wall 68B of the connection trench 68. The trench insulation layer 74 separates the inter-source interconnect 70 from the semiconductor layer 14. The field plate electrode 22 and the gate electrode 24 are separated from each other and embedded in the gate trench 16. By contrast, in the example shown in FIG. 4, as the electrode, only the inter-source interconnect 70 is embedded in the connection trench 68. The inter-source interconnect 70 and the trench insulation layer 74 are embedded in the connection trench 68 and covered by the insulation layer 18. Thus, the side surface and the bottom surface of the inter-source interconnect 70 are covered by the trench insulation layer 74, and the upper surface of the inter-source interconnect 70 is covered by the insulation layer 18.

FIG. 5 is a schematic cross-sectional view of the semiconductor device 10 taken along line F5-F5 in FIG. 1. FIG. 5 shows a cross section of one connection trench 68 in the YZ plane. As shown in FIG. 5, the connection trench 68 extends across the first source interconnect 50 and the second source interconnect 52 under the gate interconnect 54 (in FIG. 5, the second gate interconnect part 54A2). The connection trench 68 and the inter-source interconnect 70, which is embedded in the connection trench 68, intersect the gate interconnect 54 and overlap with the first source interconnect 50 and the second source interconnect 52 in plan view. Thus, the inter-source interconnect 70 extends from the inside to the outside of the closed loop of the gate interconnect 54.

The inter-source interconnect 70 is covered by the insulation layer 18. The gate interconnect 54, the first source interconnect 50, and the second source interconnect 52 are formed on the insulation layer 18. The insulation layer 18 includes contacts 76A and 76B. The inter-source interconnect 70 is connected to the first source interconnect 50 by the contact 76A and the second source interconnect 52 by the contact 76B. The contacts 76A and 76B may be embedded in contact trenches 78A and 78B formed in the insulation layer 18. As described above, the inter-source interconnect 70 is separated from the gate interconnect 54 by the insulation layer 18 and extends under the gate interconnect 54 to electrically connect the first source interconnect 50 and the second source interconnect 52.

More specifically, the inter-source interconnect 70 includes a first connecting portion 70A connected to the first source interconnect 50 by the contact 76A and a second connecting portion 70B connected to the second source interconnect 52 by the contact 76B. The inter-source interconnect 70 further includes an intermediate portion 70C extending between the first connecting portion 70A and the second connecting portion 70B. The intermediate portion 70C extends in a direction in which the connection trench 68 extends (in the example shown in FIG. 5, the Y-direction). The intermediate portion 70C is located below the gate interconnect 54. The insulation layer 18 is arranged between the intermediate portion 70C and the gate interconnect 54.

In the example shown in FIG. 5, the first connecting portion 70A and the second connecting portion 70B correspond to two ends of the inter-source interconnect 70. Alternatively, in another example, the first connecting portion 70A and the second connecting portion 70B may be located at positions separate from the ends of the inter-source interconnect 70, that is, between the two ends.

The first connecting portion 70A may be located below at least the first source interconnect 50 so as to be connected to the first source interconnect 50 by the contact 76A. In an example, the first connecting portion 70A includes a contact receptacle configured to receive a distal end of the contact 76A. The distal end of the contact 76A is inserted into the contact receptacle.

In the same manner, the second connecting portion 70B may be located below at least the second source interconnect 52 so as to be connected to the second source interconnect 52 by the contact 76B. In an example, the second connecting portion 70B includes a contact receptacle configured to receive a distal end of the contact 76B. The distal end of the contact 76B is inserted into the contact receptacle.

Regardless of whether the first connecting portion 70A and the second connecting portion 70B are the ends of the inter-source interconnect 70, the first connecting portion 304A is arranged to overlap the first source interconnect 50 in plan view, and the second connecting portion 304B is arranged to overlap the second source interconnect 52 in plan view.

As the distance between the first connecting portion 70A and the second connecting portion 70B decreases, the resistance becomes lower in the connection between the first source interconnect 50 and the second source interconnect 52. Hence, the first connecting portion 70A and the second connecting portion 70B may be arranged close to each other as long as the first connecting portion 70A is located below at least the first source interconnect 50 and the second connecting portion 70B is located below at least the second source interconnect 52.

As shown in FIG. 5, a first thickness d1 refers to the thickness of the first connecting portion 70A, a second thickness d2 refers to the second connecting portion 70B, and a third thickness d3 refers to the intermediate portion 70C.

In the present embodiment, the first thickness d1 is the thickness of a portion of the first connecting portion 70A excluding the contact receptacle and is, for example, the thickness of a peripheral portion of the contact receptacle of the first connecting portion 70A. The second thickness d2 is the thickness of a portion of the second connecting portion 70B excluding the contact receptacle and is, for example, the thickness of a peripheral portion of the contact receptacle of the second connecting portion 70B.

In the present embodiment, the first thickness d1, the second thickness d2, and the third thickness d3 are the same. More specifically, in the present embodiment, the intermediate portion 70C has the same thickness (the third thickness d3) as the first connecting portion 70A and the second connecting portion 70B in a direction (the Z-direction) orthogonal to the second surface 14B of the semiconductor layer 14. In this specification, “having the same thickness” means that the difference in thickness is within a manufacturing variation range (for example, 20%).

The two ends of the connection trench 68 are connected to the trench parts 72A1 and 72A2 of the peripheral trench 72 extending in the X-direction (refer to FIG. 1). Thus, the ends (in the example shown in FIG. 5, the first connecting portion 70A and the second connecting portion 70B) of the inter-source interconnect 70 are located in the trench parts 72A1 and 72A2 extending in the peripheral trench 72 in the X-direction.

The contact trenches 78A and 78B may be formed to respectively overlap the trench parts 72A1 and 72A2 of the peripheral trench 72 in plan view. In plan view, the contact trenches 78A and 78B each have a smaller area than the trench part 72A1 or 72A2. In this case, the inter-source interconnects 70, which are embedded in the connection trenches 68, are connected to each other in the peripheral trench 72. In an example, a conductive joint may be arranged in the trench part 72A1 of the peripheral trench 72 to connect an end (for example, the first connecting portion 70A) of each inter-source interconnect 70 to an end (for example, the first connecting portion 70A) of an adjacent inter-source interconnect 70. In the same manner, the conductive joint may be arranged in the trench part 72A2 of the peripheral trench 72 to connect an end (for example, the second connecting portion 70B) of each inter-source interconnect 70 to an end (for example, the second connecting portion 70B) of an adjacent inter-source interconnect 70. In other words, the semiconductor device 10 may further include a conductive joint arranged in the peripheral trench 72 so that the conductive joint joins the inter-source interconnects 70, which are embedded in the connection trenches 68. The conductive joint may be formed from a conductive polysilicon in the same manner as the inter-source interconnects 70. Thus, the inter-source interconnects 70 may be formed integrally from the conductive polysilicon. In an example in which the peripheral trench 72 does not include the two trench parts 72A1 and 72A2 connected to the connection trenches 68, the inter-source interconnects 70 may be separately formed in the semiconductor layer 14. In this case, each inter-source interconnect 70 may be connected to the first source interconnect 50 and the second source interconnect 52 by contacts embedded in vias formed in the insulation layer 18.

As described above, the connection structure 66 may be arranged to at least partially overlap all of the first source interconnect 50, the second source interconnect 52, and the gate interconnect 54 in plan view. The connection structure 66 (the connection trench 68) intersects the gate interconnect 54 in plan view (refer to FIG. 1). However, the inter-source interconnect 70, which is embedded in the connection trench 68, extends under the gate interconnect 54 and thus is not electrically connected to the gate interconnect 54. The connection structure 66 electrically connects the first source interconnect 50, which is located inside the loop of the gate interconnect 54, and the second source interconnect 52, which is located outside the loop of the gate interconnect 54, without breaking the gate interconnect 54.

In addition, the inter-source interconnect 70 electrically connects the first end 22A and the second end 22B of the field plate electrode 22 with a distance that is less than the distance between the first source interconnect 50 and the second source interconnect 52. Thus, the first source interconnect 50 and the second source interconnect 52, which are connected by the inter-source interconnect 70 having a relatively low resistance, have the same potential.

The operation of the semiconductor device 10 of the present embodiment will be described below.

In the semiconductor device 10 of the present embodiment, the inter-source interconnect 70, which is embedded in the connection trench 68 formed in the second surface 14B of the semiconductor layer 14, electrically connects the first source interconnect 50 and the second source interconnect 52. With this structure, the first source interconnect 50 and the second source interconnect 52 have the same potential without breaking the gate interconnect 54.

In addition, each of the field plate electrodes 22 includes the first end 22A connected to the first source interconnect 50 and the second end 22B connected to the second source interconnect 52. With this structure, the length of the gate trench 16 is substantially reduced to approximately ½ as compared to a structure in which only one end of the field plate electrode 22 is connected to the first source interconnect 50 or the second source interconnect 52. The length of the gate trench 16 contributes to the resistance Rₛ of the field plate electrode 22.

In a MISFET having the split-gate structure in which the field plate electrode and the gate electrode are embedded in the gate trench, during high-speed switching, displacement current may flow to the resistance Rₛ of the field plate electrode and increase the potential of the field plate electrode. Such increases in the potential decrease the breakdown voltage of the MISFET. Consequently, the MISFET may enter the dynamic avalanche mode. In addition, when high-speed switching is performed at a high gate resistance R_{g}, coupling of the source and the drain may result in a self turn-on that erroneously turns on the MISFET. Such phenomena are collectively referred to as a shoot-through phenomenon. When an unintended through current flows to a circuit that includes an MISFET, switching loss will be increased. In this regard, it is desirable that the shoot-through phenomenon be avoided.

The shoot-through phenomenon may occur due to a displacement current flowing through the resistance Rₛ of the field plate electrode and/or the gate resistance R_{g} Thus, the shoot-through phenomenon may be avoided by decreasing the resistance Rₛ and the resistance R_{g}. In the semiconductor device 10 of the present disclosure, as described above, the length of the gate trench 16, which contributes to the resistance Rₛ of the field plate electrode 22, is substantially reduced to ½ to avoid the shoot-through phenomenon.

In the present embodiment, the gate interconnect 54 forms a closed loop in plan view. This structure decreases the gate resistance R_{g} as compared to a structure in which the gate interconnect 54 forms an open loop.

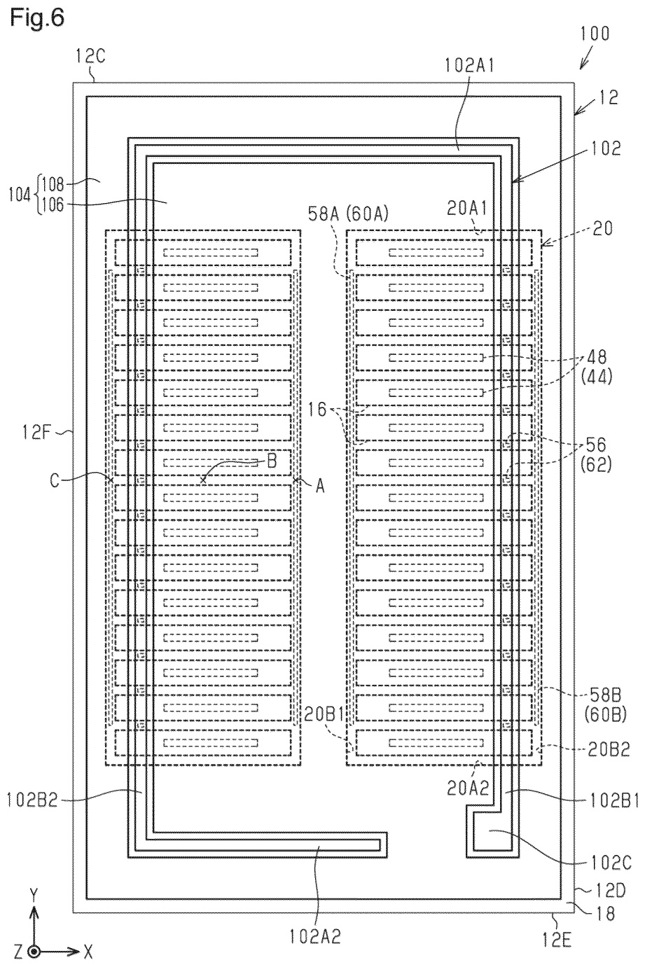

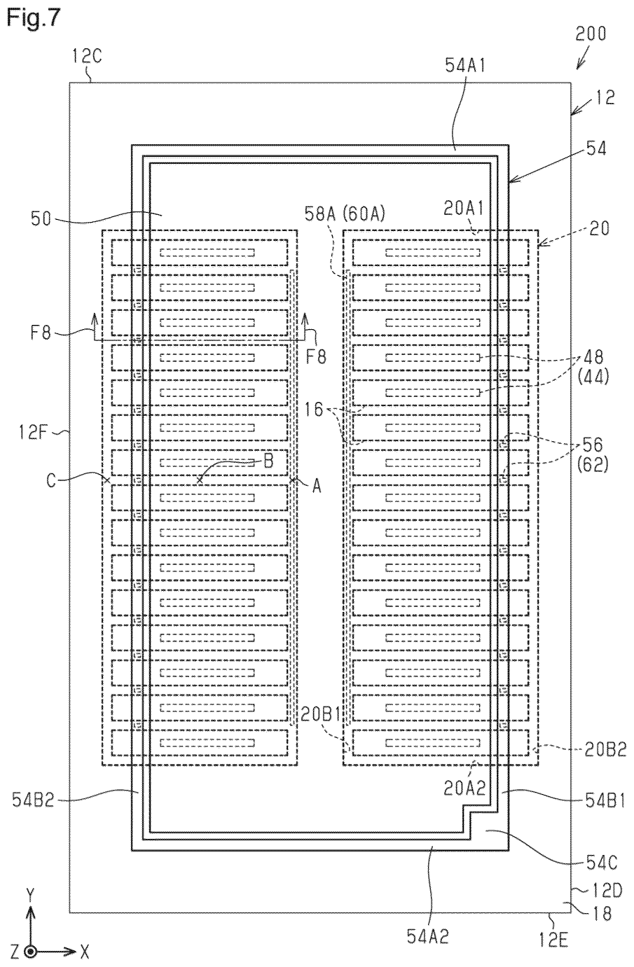

The resistance Rₛ and the resistance R_{g} of the first to third examples will be described with reference to FIGS. 6 to 9. In the description hereafter, the first example refers to a semiconductor device 100 shown in FIG. 6. The second example refers to the semiconductor device 200 shown in FIG. 7. The third example refers to the semiconductor device 10 shown in FIG. 1.

FIG. 6 is a schematic plan view of the semiconductor device 100 in the first example. In FIG. 6, the same reference characters are given to those elements that are the same as the corresponding elements of the semiconductor device 10 shown in FIG. 1. Such elements will not be described in detail.

The semiconductor device 100 includes a gate interconnect 102 formed on the insulation layer 18. The gate interconnect 102 differs from the gate interconnect 54 shown in FIG. 1 in that the gate interconnect 102 forms an open loop in plan view.

The gate interconnect 102 may include a first gate interconnect part 102A1 and a second gate interconnect part 102A2 extending in the X-direction and a third gate interconnect part 102B1 and a fourth gate interconnect part 102B2 extending in the Y-direction. In the example shown in FIG. 6, the first gate interconnect part 102A1 is located toward the side 12C of the semiconductor substrate 12. The second gate interconnect part 102A2 is located toward the side 12E of the semiconductor substrate 12. The third gate interconnect part 102B1 is located toward the side 12D of the semiconductor substrate 12. The fourth gate interconnect part 102B2 is located toward the side 12F of the semiconductor substrate 12. The first gate interconnect part 102A1 is connected to one end of the third gate interconnect part 102B1 and one end of the fourth gate interconnect part 102B2. The second gate interconnect part 102A2 is connected to the other end of the fourth gate interconnect part 102B2 but is not connected to the other end of the third gate interconnect part 102B1. Thus, the gate interconnect 102 forms a rectangular open loop in plan view. The opening of the loop of the gate interconnect 102 corresponds to the gap between the second gate interconnect part 102A2 and the third gate interconnect part 102B1. The gate interconnect 102 further includes a gate pad 102C. The gate pad 102C is connected to the third gate interconnect part 102B1.

The semiconductor device 100 further includes a source interconnect 104 formed on the insulation layer 18. The source interconnect 104 includes an inner source interconnect part 106 partially surrounded by the gate interconnect 102 and a perimeter source interconnect part 108 surrounding the gate interconnect 102. The inner source interconnect part 106 and the perimeter source interconnect part 108 differ from the first source interconnect 50 and the second source interconnect 52 shown in FIG. 1 in that the inner source interconnect part 106 and the perimeter source interconnect part 108 are connected to each other. The inner source interconnect part 106 and the perimeter source interconnect part 108 are joined through the opening of the loop of the gate interconnect 102 and thus have the same potential.

In the first example, the inner source interconnect part 106 and the perimeter source interconnect part 108 are connected to each other through the opening of the loop of the gate interconnect 102. Thus, the semiconductor device 100 does not include the connection structure 66, which electrically connects the first source interconnect 50 and the second source interconnect 52, and the peripheral trench 72 surrounding the connection structure 66 as in the third example. In the third example, the connection structure 66 allows the first source interconnect 50 and the second source interconnect 52 to have the same potential without breaking the loop of the gate interconnect 54. The gate resistance R_{g} of the third example in which the gate interconnect 54 forms the closed loop is reduced by approximately 30% from the gate resistance R_{g} of the first example in which the gate interconnect 102 forms the open loop. This shows that breakage of the loop of the gate interconnect may increase the gate resistance R_{g}.

FIG. 7 is a schematic plan view of the semiconductor device 200 in the second example. In FIG. 7, the same reference characters are given to those elements that are the same as the corresponding elements of the semiconductor device 10 shown in FIG. 1. Such elements will not be described in detail.

In the same manner as shown in FIG. 1, the semiconductor device 200 includes the gate interconnect 54 forming a closed loop in plan view and the first source interconnect 50 disposed inside the loop of the gate interconnect 54. The semiconductor device 200 does not include the second source interconnect 52 disposed outside the loop of the gate interconnect 54. Thus, the semiconductor device 200 does not include the connection structure 66, which electrically connects the first source interconnect 50 and the second source interconnect 52, and the peripheral trench 72 surrounding the connection structure 66.

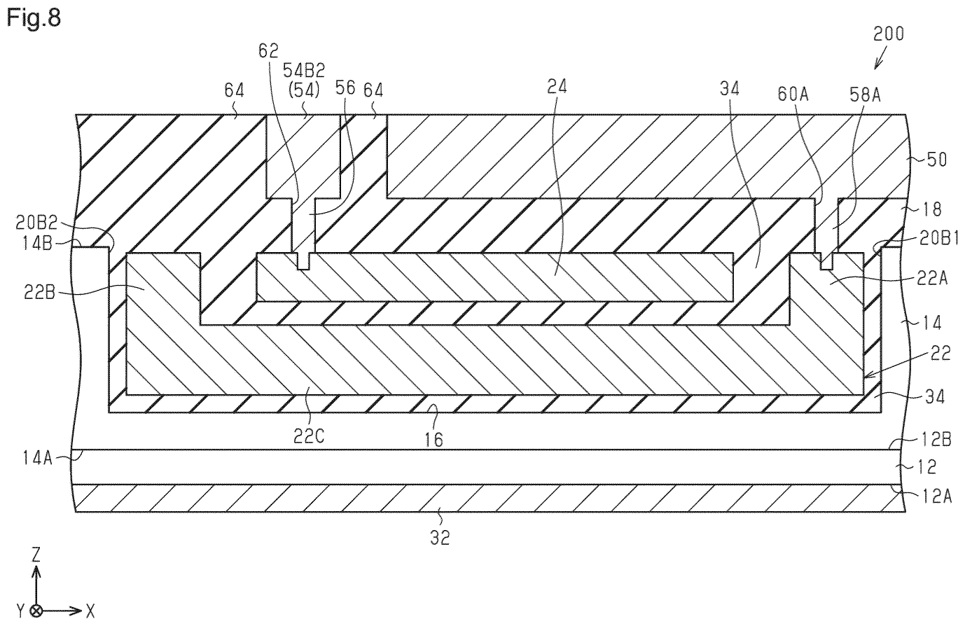

FIG. 8 is a schematic cross-sectional view of the semiconductor device 10 taken along line F8-F8 in FIG. 7 showing a cross section of a gate trench 16 formed in the semiconductor layer 14 along the XZ-plane.

The field plate electrode 22 is connected to the first source interconnect 50 by a single field plate contact 58A. More specifically, the first end 22A of the field plate electrode 22 is connected to the first source interconnect 50 by the field plate contact 58A. In contrast, the second end 22B is not connected to any of the interconnects because the second example does not include the second source interconnect 52.

As described above, in the second example, only one end of each field plate electrode 22 is connected to the first source interconnect 50. Thus, the resistance Rₛ of the field plate electrode 22 may be produced in correspondence with the length of the field plate electrode 22.

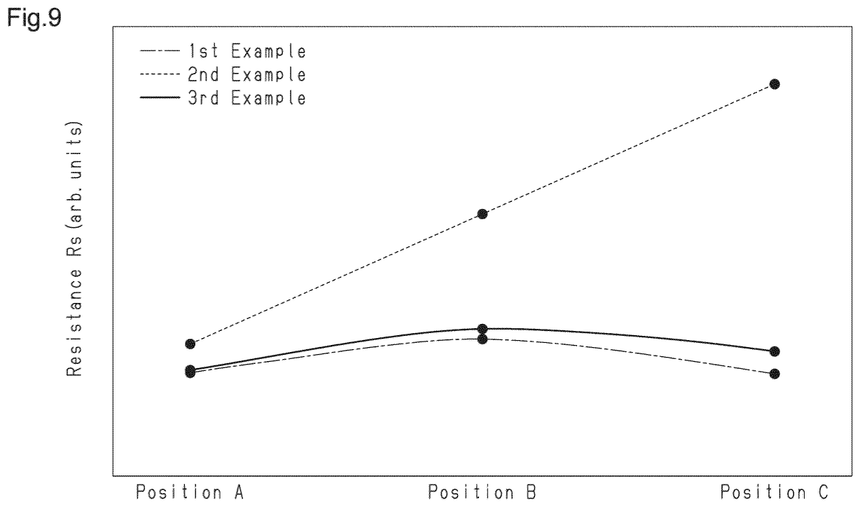

FIG. 9 is a graph showing the resistance Rₛ of the field plate electrode 22 in the first to third examples. The vertical axis of the graph indicates resistance Rₛ. The horizontal axis of the graph indicates positions A, B, and C at which the resistance Rₛ is measured. The positions A, B, and C are arranged in a direction (i.e., the X-direction) in which the gate trench 16 extends in plan view (refer to FIGS. 1, 6, and 7). The position A corresponds to the position of the first end 22A of the field plate electrode 22. The position B corresponds to an intermediate position between the first end 22A and the second end 22B of the field plate electrode 22. The position C corresponds to the position of the second end 22B of the field plate electrode 22. In the graph, the resistance Rₛ of the first example is indicated by the single-dashed line, the resistance Rₛ of the second example is indicated by the broken line, and the resistance Rₛ of the third example is indicated by the solid line.

The position A corresponds to a position at which the field plate electrode 22 is connected to the source interconnect (the first source interconnect 50 or the inner source interconnect part 106) by the field plate contact 58A. Therefore, in each of the first to third examples, the resistance Rₛ is relatively low at the position A.

The second example does not include a source interconnect corresponding to the second source interconnect 52. Therefore, the resistance Rₛ tends to increase as the position at which the field plate electrode 22 is connected to the first source interconnect 50 (i.e., the position A) becomes farther. In the second example, the resistance Rₛ is highest at the position C. This shows that the length of the field plate electrode 22 contributes to the resistance Rₛ.

In the first and third examples, the position C corresponds to a position at which the field plate electrode 22 is connected to the source interconnect (the second source interconnect 52 or the perimeter source interconnect part 108) by the field plate contact 58B. Therefore, in the first and third examples, the resistance Rₛ is relatively low at the position C in the same manner as the resistance Rₛ at the position A. Since the position B is located between the position A and the position C, the resistance Rₛ at the position B is slightly higher than the resistances Rₛ at the position A and the position C. However, in the first and third examples, both the first end 22A and the second end 22B of the field plate electrode 22 are connected to the source interconnect. Therefore, the resistance Rₛ of the first and third examples is lower than the resistance Rₛ of the second example at any position.

As described above, when both the first end 22A and the second end 22B of the field plate electrode 22 are connected to the source interconnect, the resistance Rₛ is decreased. However, when the first end 22A and the second end 22B of the field plate electrode 22 are embedded in the gate trench 16, intersecting with the gate interconnect 54, and connected to source interconnects, it is desirable that a source interconnect disposed inside the loop of the gate interconnect 54 and a source interconnect disposed outside the loop of the gate interconnect 54 be connected to each other to have the same potential. In the first example, the source interconnect disposed inside the loop is connected to the source interconnect disposed outside the loop by partially breaking the loop of the gate interconnect 54. However, this results in an increase in the gate resistance R_{g}. In the third example, the connection structure 66 allows the source interconnect disposed inside the loop and the source interconnect disposed outside the loop to have the same potential without breaking the loop of the gate interconnect 54. Thus, in the third example, that is, in the semiconductor device 10 of the present embodiment, the resistance Rₛ of the field plate electrode 22 is decreased while limiting an increase in the gate resistance R_{g}.

The semiconductor device 10 of the present embodiment has the following advantages.

(1) The inter-source interconnect 70, which is embedded in the connection trench 68 intersecting the gate interconnect 54 in plan view, electrically connects the first source interconnect 50 and the second source interconnect 52. With this structure, while the loop of the gate interconnect 54 remains closed, the first source interconnect 50, which is disposed inside the loop of the gate interconnect 54, and the second source interconnect 52, which is disposed outside the loop of the gate interconnect 54, are connected to each other and have the same potential. As a result, an increase in the gate resistance R_{g} of the semiconductor device 10 is limited.

(2) Each of the field plate electrodes 22 includes the first end 22A connected to the first source interconnect 50 and the second end 22B connected to the second source interconnect 52. With this structure, the length of the gate trench, which contributes to the resistance Rₛ of the field plate electrode 22, is substantially reduced to approximately ½ as compared to a structure in which only one end of the field plate electrode 22 is connected.

(3) The inter-source interconnect 70 electrically connects the first end 22A and the second end 22B of the field plate electrode 22 with a distance that is less than the distance between the first source interconnect 50 and the second source interconnect 52. With this structure, the first source interconnect 50 and the second source interconnect 52 are connected at a smaller resistance and thus have the same potential.

(4) The semiconductor device 10 may include multiple connection structures 66. With this structure, the first source interconnect 50 and the second source interconnect 52 are connected at a smaller resistance and thus have the same potential.

### First Modified Example of Connection Structure

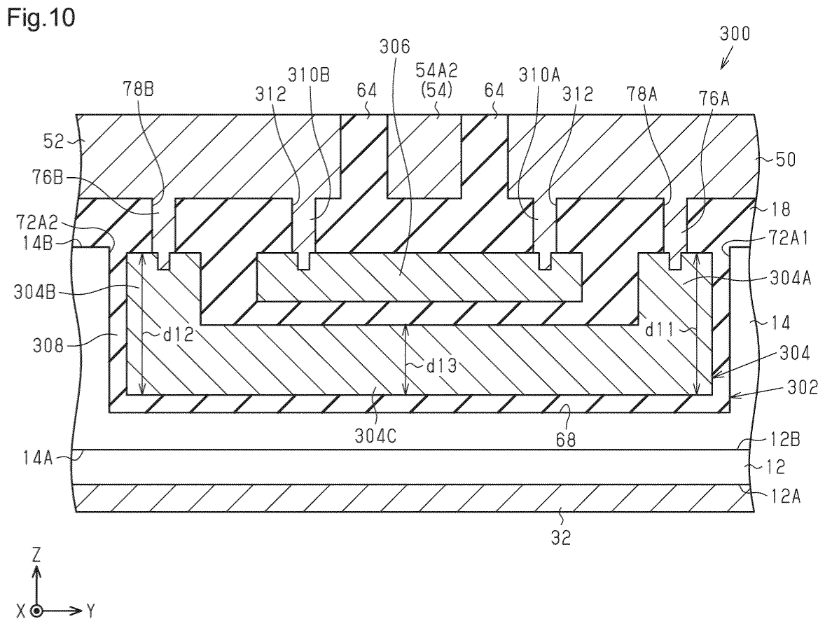

FIG. 10 is a schematic cross-sectional view showing an exemplary semiconductor device 300 in a first modified example of the above embodiment. FIG. 10 corresponds to the cross section along line F5-F5 in FIG. 1. In FIG. 10, the same reference characters are given to those elements that are the same as the corresponding elements of the semiconductor device 10 shown in FIG. 1. Such elements will not be described in detail.

The semiconductor device 300 includes a connection structure 302. The connection structure 302 includes the connection trench 68 formed in the second surface 14B of the semiconductor layer 14 and an inter-source interconnect 304 embedded in the connection trench 68. In an example, the inter-source interconnect 304 may be formed from a conductive polysilicon. The inter-source interconnect 304 and the field plate electrode 22 may be formed from the same material. The connection trench 68 and the inter-source interconnect 304, which is embedded in the connection trench 68, intersect the gate interconnect 54 and overlap with the first source interconnect 50 and the second source interconnect 52 in plan view. Thus, the inter-source interconnect 304 extends from the inside to the outside of the closed loop of the gate interconnect 54.

The inter-source interconnect 304 includes a first connecting portion 304A connected to the first source interconnect 50 by the contact 76A and a second connecting portion 304B connected to the second source interconnect 52 by the contact 76B. The first connecting portion 304A and the second connecting portion 304B of the inter-source interconnect 304 extend from the bottom to the opening of the connection trench 68 in the Z-direction. In an example, the first connecting portion 304A includes a contact receptacle configured to receive a distal end of the contact 76A. The distal end of the contact 76A is inserted into the contact receptacle. In an example, the second connecting portion 304B includes a contact receptacle configured to receive a distal end of the contact 76B. The distal end of the contact 76B is inserted into the contact receptacle.

The inter-source interconnect 304 further includes an intermediate portion 304C extending between the first connecting portion 304A and the second connecting portion 304B. The intermediate portion 304C extends in a direction in which the connection trench 68 extends (in the example shown in FIG. 10, the Y-direction).

In the example shown in FIG. 10, the first connecting portion 304A and the second connecting portion 304B correspond to two ends of the inter-source interconnect 304. Alternatively, in another example, the first connecting portion 304A and the second connecting portion 304B may be located at positions separate from the ends of the inter-source interconnect 304, that is, between the two ends. Regardless of whether the first connecting portion 304A and the second connecting portion 304B are the ends of the inter-source interconnect 304, the first connecting portion 304A is arranged to overlap the first source interconnect 50 in plan view, and the second connecting portion 304B is arranged to overlap the second source interconnect 52 in plan view.

As shown in FIG. 10, the intermediate portion 304C has a smaller thickness (third thickness d13) than the first connecting portion 304A and the second connecting portion 304B in a direction (the Z-direction) orthogonal to the second surface 14B of the semiconductor layer 14. More specifically, the third thickness d13, which is the thickness of the intermediate portion 304C, is smaller than a first thickness d11, which is the thickness of the first connecting portion 304A, and a second thickness d12, which is the thickness of the second connecting portion 304B. In the present embodiment, the first thickness d11 is the thickness of a portion of the first connecting portion 304A excluding the contact receptacle. The second thickness d12 is the thickness of a portion of the second connecting portion 304B excluding the contact receptacle. Thus, the distance between the bottom surface of the gate interconnect 54 and the upper surface of the intermediate portion 304C is relatively increased.

The connection structure 302 further includes a conductive layer 306 insulated from the inter-source interconnect 304 and embedded in the connection trench 68. In an example, the conductive layer 306 may be formed from a conductive polysilicon. The conductive layer 306 and the gate electrode 24 may be formed from the same material. The conductive layer 306 is disposed above the intermediate portion 304C of the inter-source interconnect 304. The conductive layer 306 is at least partially disposed between the gate interconnect 54 and the inter-source interconnect 304. The intermediate portion 304C of the inter-source interconnect 304 has a smaller thickness than the first connecting portion 304A and the second connecting portion 304B. This allows the conductive layer 306 to be arranged above the intermediate portion 304C of the inter-source interconnect 304. The upper surface of the conductive layer 306 is covered by the insulation layer 18.

The connection structure 302 further includes a trench insulation layer 308 formed on the walls of the connection trench 68. The trench insulation layer 308 separates the inter-source interconnect 304, the conductive layer 306, and the semiconductor layer 14 from each other. In the same manner as the field plate electrode 22 and the gate electrode 24 are separated from each other and embedded in the gate trench 16, the inter-source interconnect 304 and the conductive layer 306 are separated from each other and embedded as electrodes in the connection trench 68. The trench insulation layer 308, the inter-source interconnect 304, and the conductive layer 306 are embedded in the connection trench 68 and covered by the insulation layer 18.

The inter-source interconnect 304 electrically connects the first source interconnect 50 and the second source interconnect 52. The inter-source interconnect 304 is connected to the first source interconnect 50 by the contact 76A and the second source interconnect 52 by the contact 76B. The contacts 76A and 76B may be embedded in the contact trenches 78A and 78B formed in the insulation layer 18. The two ends of the connection trench 68 are connected to the trench parts 72A1 and 72A2 of the peripheral trench 72 extending in the X-direction (refer to FIG. 1). Thus, the ends (in the example shown in FIG. 10, the first connecting portion 304A and the second connecting portion 304B) of the inter-source interconnect 304 are located in the trench parts 72A1 and 72A2 extending in the peripheral trench 72 in the X-direction.

The conductive layer 306 electrically connects the first source interconnect 50 and the second source interconnect 52. Hence, in the first modified example, the conductive layer 306 may be referred to as a second inter-source interconnect. The conductive layer 306 is connected to the first source interconnect 50 by a contact 310A and the second source interconnect 52 by a contact 310B. The contacts 310A and 310B may be embedded in contact vias 312 formed in the insulation layer 18. The contact vias 312 may overlap the connection trench 68 in plan view. In the example shown in FIG. 10, two contact vias 312 are located between the contact trenches 78A and 78B in plan view. The gate interconnect 54 (the second gate interconnect part 54A2) is located between the two contact vias 312 in plan view.

As described above, the connection structure 302 may be arranged to at least partially overlap all of the first source interconnect 50, the second source interconnect 52, and the gate interconnect 54 in plan view. The connection structure 302 (the connection trench 68) intersects the gate interconnect 54 in plan view (refer to FIG. 1). However, the inter-source interconnect 304 and the conductive layer 306, which are embedded in the connection trench 68, extend under the gate interconnect 54 and thus are not electrically connected to the gate interconnect 54. The connection structure 302 electrically connects the first source interconnect 50, which is located inside the loop of the gate interconnect 54, and the second source interconnect 52, which is located outside the loop of the gate interconnect 54, without breaking the gate interconnect 54.

### Second Modified Example of Connection Structure

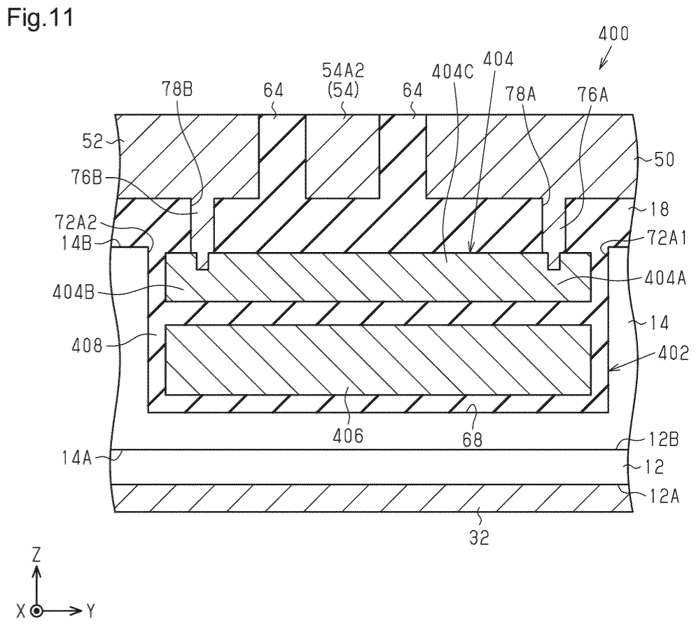

FIG. 11 is a schematic cross-sectional view showing an exemplary semiconductor device 400 in a second modified example of the above embodiment. FIG. 11 corresponds to the cross section along line F5-F5 in FIG. 1. In FIG. 11, the same reference characters are given to those elements that are the same as the corresponding elements of the semiconductor device 10 shown in FIG. 1. Such elements will not be described in detail.

The semiconductor device 400 includes a connection structure 402. The connection structure 402 includes the connection trench 68 formed in the second surface 14B of the semiconductor layer 14 and an inter-source interconnect 404 embedded in the connection trench 68. In an example, the inter-source interconnect 404 may be formed from a conductive polysilicon. The inter-source interconnect 404 and the gate electrode 24 may be formed from the same material. The connection trench 68 and the inter-source interconnect 404, which is embedded in the connection trench 68, intersect the gate interconnect 54 and overlap with the first source interconnect 50 and the second source interconnect 52 in plan view. Thus, the inter-source interconnect 404 extends from the inside to the outside of the closed loop of the gate interconnect 54.

The inter-source interconnect 404 includes a first connecting portion 404A connected to the first source interconnect 50 by the contact 76A and a second connecting portion 404B connected to the second source interconnect 52 by the contact 76B. The inter-source interconnect 404 further includes an intermediate portion 404C extending between the first connecting portion 404A and the second connecting portion 404B. The intermediate portion 404C extends in a direction in which the connection trench 68 extends (in the example shown in FIG. 11, the Y-direction).

In the example shown in FIG. 11, the first connecting portion 404A and the second connecting portion 404B correspond to two ends of the inter-source interconnect 404. Alternatively, in another example, the first connecting portion 404A and the second connecting portion 404B may be located at positions separate from the ends of the inter-source interconnect 404, that is, between the two ends. Regardless of whether the first connecting portion 404A and the second connecting portion 404B are the ends of the inter-source interconnect 404, the first connecting portion 404A is arranged to overlap the first source interconnect 50 in plan view, and the second connecting portion 404B is arranged to overlap the second source interconnect 52 in plan view.

As the distance between the first connecting portion 404A and the second connecting portion 404B decreases, the resistance becomes lower in the connection between the first source interconnect 50 and the second source interconnect 52. Hence, the first connecting portion 404A and the second connecting portion 404B may be arranged close to each other as long as the first connecting portion 404A is located below at least the first source interconnect 50 and the second connecting portion 404B is located below at least the second source interconnect 52.

As shown in FIG. 11, the intermediate portion 404C has the same thickness as the first connecting portion 404A and the second connecting portion 404B in a direction (the Z-direction) orthogonal to the second surface 14B of the semiconductor layer 14. The definition of the thickness of each portion is as described above.

The connection structure 402 further includes a conductive layer 406 insulated from the inter-source interconnect 404 and embedded in the connection trench 68. In an example, the conductive layer 406 may be formed from a conductive polysilicon. The conductive layer 406 and the field plate electrode 22 may be formed from the same material. The conductive layer 406 is located below the inter-source interconnect 404. In the example shown in FIG. 11, the conductive layer 406 and the inter-source interconnect 404 have substantially the same length in the Y-direction. However, the conductive layer 406 and the inter-source interconnect may have different lengths.

The connection structure 402 further includes a trench insulation layer 408 formed on the walls of the connection trench 68. The trench insulation layer 408 separates the inter-source interconnect 404, the conductive layer 406, and the semiconductor layer 14 from each other. In the same manner as the field plate electrode 22 and the gate electrode 24 are separated from each other and embedded in the gate trench 16, the inter-source interconnect 404 and the conductive layer 406 are separated from each other and embedded as electrodes in the connection trench 68. The trench insulation layer 408 and the inter-source interconnect 404 are embedded in the connection trench 68 and are covered by the insulation layer 18.

The inter-source interconnect 404 electrically connects the first source interconnect 50 and the second source interconnect 52. The inter-source interconnect 404 is connected to the first source interconnect 50 by the contact 76A and the second source interconnect 52 by the contact 76B. The contacts 76A and 76B may be respectively embedded in the contact trenches 78A and 78B formed in the insulation layer 18. The two ends of the connection trench 68 are connected to the trench parts 72A1 and 72A2 of the peripheral trench 72 extending in the X-direction (refer to FIG. 1). Thus, the ends (in the example shown in FIG. 11, the first connecting portion 404A and the second connecting portion 404B) of the inter-source interconnect 404 are located in the trench parts 72A1 and 72A2 extending in the peripheral trench 72 in the X-direction. The conductive layer 406 is not connected to any one of the first source interconnect 50 and the second source interconnect 52. Thus, the conductive layer 406 is electrically floating.

As described above, the connection structure 402 may be arranged to at least partially overlap all of the first source interconnect 50, the second source interconnect 52, and the gate interconnect 54 in plan view. The connection structure 402 (the connection trench 68) intersects the gate interconnect 54 in plan view (refer to FIG. 1). However, the inter-source interconnect 404 and the conductive layer 406, which are embedded in the connection trench 68, extend under the gate interconnect 54 and thus are not electrically connected to the gate interconnect 54. The connection structure 402 electrically connects the first source interconnect 50, which is located inside the loop of the gate interconnect 54, and the second source interconnect 52, which is located outside the loop of the gate interconnect 54, without breaking the gate interconnect 54.

### Third Modified Example of Connection Structure

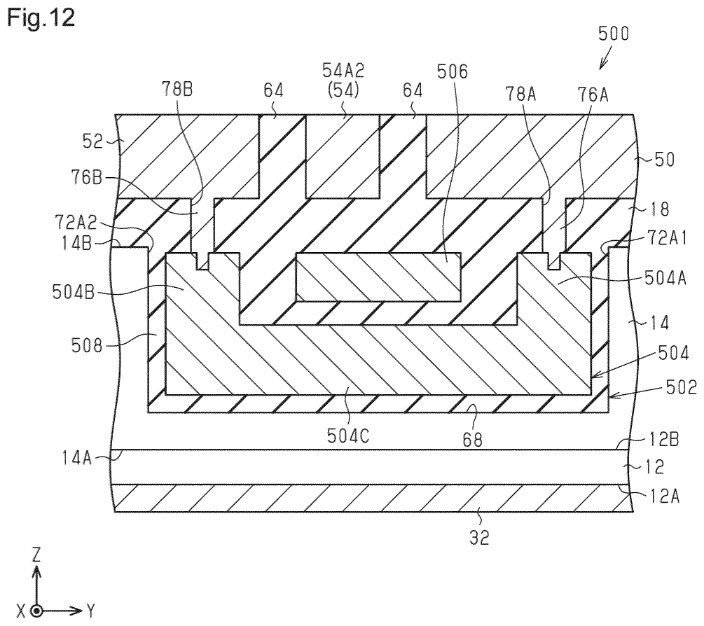

FIG. 12 is a schematic cross-sectional view showing an exemplary semiconductor device 500 in a third modified example of the above embodiment. FIG. 12 corresponds to the cross section along line F5-F5 in FIG. 1. In FIG. 12, the same reference characters are given to those elements that are the same as the corresponding elements of the semiconductor device 10 shown in FIG. 1. Such elements will not be described in detail.

The semiconductor device 500 includes a connection structure 502. The connection structure 502 includes the connection trench 68 formed in the second surface 14B of the semiconductor layer 14 and an inter-source interconnect 504 embedded in the connection trench 68. In an example, the inter-source interconnect 504 may be formed from a conductive polysilicon. The inter-source interconnect 504 and the field plate electrode 22 may be formed from the same material. The connection trench 68 and the inter-source interconnect 504, which is embedded in the connection trench 68, intersect the gate interconnect 54 and overlap with the first source interconnect 50 and the second source interconnect 52 in plan view. Thus, the inter-source interconnect 504 extends from the inside to the outside of the closed loop of the gate interconnect 54.

The inter-source interconnect 504 includes a first connecting portion 504A connected to the first source interconnect 50 by the contact 76A and a second connecting portion 504B connected to the second source interconnect 52 by the contact 76B. The first connecting portion 504A and the second connecting portion 504B of the inter-source interconnect 504 extend from the bottom to the opening of the connection trench 68 in the Z-direction. The inter-source interconnect 504 further includes an intermediate portion 504C extending between the first connecting portion 504A and the second connecting portion 504B. The intermediate portion 504C extends in a direction in which the connection trench 68 extends (in the example shown in FIG. 12, the Y-direction).

In the example shown in FIG. 12, the first connecting portion 504A and the second connecting portion 504B correspond to two ends of the inter-source interconnect 504. Alternatively, in another example, the first connecting portion 504A and the second connecting portion 504B may be located at positions separate from the ends of the inter-source interconnect 504, that is, between the two ends. Regardless of whether the first connecting portion 504A and the second connecting portion 504B are the ends of the inter-source interconnect 504, the first connecting portion 504A is arranged to overlap the first source interconnect 50 in plan view, and the second connecting portion 504B is arranged to overlap the second source interconnect 52 in plan view.

As the distance between the first connecting portion 504A and the second connecting portion 504B decreases, the resistance becomes lower in the connection between the first source interconnect 50 and the second source interconnect 52. Hence, the first connecting portion 504A and the second connecting portion 504B may be arranged close to each other as long as the first connecting portion 504A is located below at least the first source interconnect 50 and the second connecting portion 504B is located below at least the second source interconnect 52.

The intermediate portion 504C has a thickness that is smaller than that of the first connecting portion 504A and the second connecting portion 504B in a direction (the Z-direction) orthogonal to the second surface 14B of the semiconductor layer 14. Thus, the distance between the bottom surface of the gate interconnect 54 and the upper surface of the intermediate portion 504C is relatively increased. The definition of the thickness of each portion is as described above.

The connection structure 502 further includes a conductive layer 506 insulated from the inter-source interconnect 504 and embedded in the connection trench 68. In an example, the conductive layer 506 may be formed from a conductive polysilicon. The conductive layer 506 and the gate electrode 24 may be formed from the same material. The conductive layer 506 is disposed above the intermediate portion 504C of the inter-source interconnect 504. The conductive layer 506 is at least partially disposed between the gate interconnect 54 and the inter-source interconnect 504. The intermediate portion 504C of the inter-source interconnect 504 has a smaller thickness than the first connecting portion 504A and the second connecting portion 504B. Thus, the conductive layer 506 may be arranged above the intermediate portion 504C of the inter-source interconnect 504. The upper surface of the conductive layer 506 is covered by the insulation layer 18.

The connection structure 502 further includes a trench insulation layer 508 formed on the walls of the connection trench 68. The trench insulation layer 508 separates the inter-source interconnect 504, the conductive layer 506, and the semiconductor layer 14 from each other. In the same manner as the field plate electrode 22 and the gate electrode 24 are separated from each other and embedded in the gate trench 16, the inter-source interconnect 504 and the conductive layer 506 are separated from each other and embedded as electrodes in the connection trench 68. The trench insulation layer 508, the inter-source interconnect 504, and the conductive layer 506 are embedded in the connection trench 68 and covered by the insulation layer 18.

The inter-source interconnect 504 electrically connects the first source interconnect 50 and the second source interconnect 52. The inter-source interconnect 504 is connected to the first source interconnect 50 by the contact 76A and the second source interconnect 52 by the contact 76B. The contacts 76A and 76B may be embedded in the contact trenches 78A and 78B formed in the insulation layer 18. The two ends of the connection trench 68 are connected to the trench parts 72A1 and 72A2 of the peripheral trench 72 extending in the X-direction (refer to FIG. 1). Thus, the ends (in the example shown in FIG. 12, the first connecting portion 504A and the second connecting portion 504B) of the inter-source interconnect 504 are located in the trench parts 72A1 and 72A2 extending in the peripheral trench 72 in the X-direction. The conductive layer 506 is not connected to any one of the first source interconnect 50 and the second source interconnect 52. Thus, the conductive layer 506 is electrically floating.

As described above, the connection structure 502 may be arranged to at least partially overlap all of the first source interconnect 50, the second source interconnect 52, and the gate interconnect 54 in plan view. The connection structure 502 (the connection trench 68) intersects the gate interconnect 54 in plan view (refer to FIG. 1). However, the inter-source interconnect 504 and the conductive layer 506, which are embedded in the connection trench 68, extend under the gate interconnect 54 and thus are not electrically connected to the gate interconnect 54. The connection structure 502 electrically connects the first source interconnect 50, which is located inside the loop of the gate interconnect 54, and the second source interconnect 52, which is located outside the loop of the gate interconnect 54, without breaking the gate interconnect 54.

### Fourth Modified Example of Connection Structure

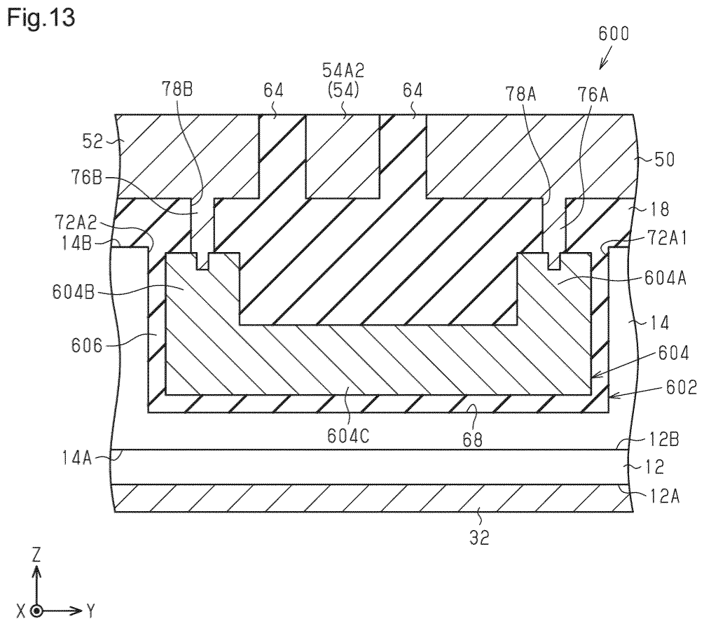

FIG. 13 is a schematic cross-sectional view showing an exemplary semiconductor device 600 in a fourth modified example of the above embodiment. FIG. 13 corresponds to the cross section along line F5-F5 in FIG. 1. In FIG. 13, the same reference characters are given to those elements that are the same as the corresponding elements of the semiconductor device 10 shown in FIG. 1. Such elements will not be described in detail.

The semiconductor device 600 includes a connection structure 602. The connection structure 602 includes the connection trench 68 formed in the second surface 14B of the semiconductor layer 14 and an inter-source interconnect 604 embedded in the connection trench 68. In an example, the inter-source interconnect 604 may be formed from a conductive polysilicon. The inter-source interconnect 604 and the field plate electrode 22 may be formed from the same material. The connection trench 68 and the inter-source interconnect 604, which is embedded in the connection trench 68, intersect the gate interconnect 54 and overlap with the first source interconnect 50 and the second source interconnect 52 in plan view. Thus, the inter-source interconnect 604 extends from the inside to the outside of the closed loop of the gate interconnect 54.

The inter-source interconnect 604 includes a first connecting portion 604A connected to the first source interconnect 50 by the contact 76A and a second connecting portion 604B connected to the second source interconnect 52 by the contact 76B. The first connecting portion 604A and the second connecting portion 604B of the inter-source interconnect 604 extend from the bottom to the opening of the connection trench 68 in the Z-direction. The inter-source interconnect 604 further includes an intermediate portion 604C extending between the first connecting portion 604A and the second connecting portion 604B. The intermediate portion 604C extends in a direction in which the connection trench 68 extends (in the example shown in FIG. 13, the Y-direction).

In the example shown in FIG. 13, the first connecting portion 604A and the second connecting portion 604B correspond to two ends of the inter-source interconnect 604. Alternatively, in another example, the first connecting portion 604A and the second connecting portion 604B may be located at positions separate from the ends of the inter-source interconnect 604, that is, between the two ends. Regardless of whether the first connecting portion 604A and the second connecting portion 604B are the ends of the inter-source interconnect 604, the first connecting portion 604A is arranged to overlap the first source interconnect 50 in plan view, and the second connecting portion 604B is arranged to overlap the second source interconnect 52 in plan view.

As the distance between the first connecting portion 604A and the second connecting portion 604B decreases, the resistance becomes lower in the connection between the first source interconnect 50 and the second source interconnect 52. Hence, the first connecting portion 604A and the second connecting portion 604B may be arranged close to each other as long as the first connecting portion 604A is located below at least the first source interconnect 50 and the second connecting portion 604B is located below at least the second source interconnect 52.

The intermediate portion 604C has a thickness that is smaller than that of the first connecting portion 604A and the second connecting portion 604B in a direction (the Z-direction) orthogonal to the second surface 14B of the semiconductor layer 14. Thus, the distance between the bottom surface of the gate interconnect 54 and the upper surface of the intermediate portion 604C is relatively increased. The definition of the thickness of each portion is as described above.

The connection structure 602 further includes a trench insulation layer 606 formed on the walls of the connection trench 68. The trench insulation layer 606 separates the inter-source interconnect 604 from the semiconductor layer 14. The field plate electrode 22 and the gate electrode 24 are separated from each other and embedded in the gate trench 16. By contrast, as the electrode, only the inter-source interconnect 604 is embedded in the connection trench 68. The trench insulation layer 606 and the inter-source interconnect 604 are embedded in the connection trench 68 and covered by the insulation layer 18.

The inter-source interconnect 604 electrically connects the first source interconnect 50 and the second source interconnect 52. The inter-source interconnect 604 is connected to the first source interconnect 50 by the contact 76A and the second source interconnect 52 by the contact 76B. The contacts 76A and 76B may be embedded in the contact trenches 78A and 78B formed in the insulation layer 18. The two ends of the connection trench 68 are connected to the trench parts 72A1 and 72A2 of the peripheral trench 72 extending in the X-direction (refer to FIG. 1). Thus, the ends (in the example shown in FIG. 13, the first connecting portion 604A and the second connecting portion 604B) of the inter-source interconnect 504 are located in the trench parts 72A1 and 72A2 extending in the peripheral trench 72 in the X-direction.

As described above, the connection structure 602 may be arranged to at least partially overlap all of the first source interconnect 50, the second source interconnect 52, and the gate interconnect 54 in plan view. The connection structure 602 (the connection trench 68) intersects the gate interconnect 54 in plan view (refer to FIG. 1). However, the inter-source interconnect 604, which is embedded in the connection trench 68, extends under the gate interconnect 54 and thus is not electrically connected to the gate interconnect 54. The connection structure 602 electrically connects the first source interconnect 50, which is located inside the loop of the gate interconnect 54, and the second source interconnect 52, which is located outside the loop of the gate interconnect 54, without breaking the gate interconnect 54.

### Other Modified Examples

The embodiment and the modified examples described above may be modified as follows.

Instead of the multiple gate trenches 16, a single gate trench 16 may be formed in the semiconductor layer 14.

The conductivity type of each region in the semiconductor layer 14 may be inverted. More specifically, a p-type region may be changed to an n-type region, and an n-type region may be changed to a p-type region.

An additional interconnect structure may be formed on the layer including the source interconnect and the gate interconnect.

The gate interconnect is not limited to forming a closed loop. In an example, the semiconductor device may include a gate interconnect forming an open loop and a connection structure. Even in this case, the connection structure decreases the resistance Rₛ of the field plate electrode 22. It is preferred that the gate interconnect forms a closed loop, which decreases the resistance Rₛ of the field plate electrode 22 while limiting increases in the gate resistance R_{g}.

The terms “connected,” “coupled,” and any other variation thereof used in the present disclosure may mean a direct or indirect connection or coupling between two or more elements.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer.

The directional terms used in the present disclosure such as “vertical,” “horizontal,” “above,” “below,” “top,” “bottom,” “frontward,” “backward,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-direction as referred to in the present description are not limited to “upward” and “downward” in the vertical direction. For example, the X-direction may conform to the vertical direction. The Y-axis direction may conform to the vertical direction.

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs used as examples to facilitate understanding, and the elements in each clause are not limited to those elements given with the reference signs.

[Clause 1]

A semiconductor device, including:
a semiconductor layer (14) including a first surface (14A) and a second surface (14B) opposite to the first surface (14A);
gate trenches (16) formed in the second surface (14B) of the semiconductor layer (14);
gate electrodes (24), each of the gate electrodes (24) being embedded in one of the gate trenches (16);
field plate electrodes (22), each of the field plate electrodes (22) being embedded in one of the gate trenches (16) and insulated from the gate electrodes (24) and including a first end (22A) and a second end (22B);
an insulation layer (18) formed on the second surface (14B) of the semiconductor layer (14);
a gate interconnect (54) formed on the insulation layer (18) and connected to each of the gate electrodes (24), the gate interconnect (54) forming a loop in plan view;
a first source interconnect (50) formed on the insulation layer (18) and connected to the first end (22A) of each of the field plate electrodes (22), the first source interconnect (50) disposed inside the loop of the gate interconnect (54) in plan view;
a second source interconnect (52) formed on the insulation layer (18) and connected to the second end (22B) of each of the field plate electrodes (22), the second source interconnect (52) disposed outside the loop of the gate interconnect (54) in plan view; and
a connection structure (66) formed in the semiconductor layer (14),
in which the connection structure (66) includes a connection trench (68) formed in the second surface (14B) of the semiconductor layer (14) and intersecting the gate interconnect (54) in plan view and an inter-source interconnect (70) embedded in the connection trench (68), and the inter-source interconnect (70) is electrically connected to the first source interconnect (50) and the second source interconnect (52).

[Clause 2]

The semiconductor device according to clause 1, in which the gate interconnect forms a closed loop in plan view.

[Clause 3]

The semiconductor device according to clause 1 or 2, in which the inter-source interconnect (70) electrically connects the first source interconnect (50) and the second source interconnect (52) with a distance less than a distance between the first end (22A) and the second end (22B) of each of the field plate electrodes (22).

[Clause 4]

The semiconductor device according to any one of clauses 1 to 3, in which the inter-source interconnect (70; 404) includes a first connecting portion (70A; 404A) connected to the first source interconnect (50), a second connecting portion (70B; 404B) connected to the second source interconnect (52), and an intermediate portion (70C; 404C) extending between the first connecting portion (70A; 404A) and the second connecting portion (70B; 404B), the intermediate portion (70C; 404C) is equal to the first connecting portion (70A; 404A) and the second connecting portion (70B; 404B) in thickness in a direction orthogonal to the second surface (14B) of the semiconductor layer (14).

[Clause 5]

The semiconductor device according to any one of clauses 1 to 3, in which the inter-source interconnect (304; 504; 604) includes a first connecting portion (304A; 504A; 604A) connected to the first source interconnect (50), a second connecting portion (304B; 504B; 604B) connected to the second source interconnect (52), and an intermediate portion (304C; 504C; 604C) extending between the first connecting portion (304A; 504A; 604A) and the second connecting portion (304B; 504B; 604B), the intermediate portion (304C; 504C; 604C) has a thickness that is smaller than that of the first connecting portion (304A; 504A; 604A) and the second connecting portion (304B; 504B; 604B) in a direction orthogonal to the second surface (14B) of the semiconductor layer (14).

[Clause 6]

The semiconductor device according to any one of clauses 1 to 5, in which the connection structure (302; 402; 502) further includes a conductive layer (306; 406; 506) insulated from the inter-source interconnect (304; 504; 604) and embedded in the connection trench (68).

[Clause 7]

The semiconductor device according to clause 6, in which the conductive layer (306) is at least partially disposed between the gate interconnect (54) and the inter-source interconnect (304) and electrically connects the first source interconnect (50) and the second source interconnect (52).

[Clause 8]

The semiconductor device according to clause 6, in which the conductive layer (406) is located below the inter-source interconnect (404) and is electrically floating.

[Clause 9]

The semiconductor device according to clause 6, in which the conductive layer (506) is at least partially disposed between the gate interconnect (54) and the inter-source interconnect (504) and is electrically floating.

[Clause 10]

The semiconductor device according to any one of clauses 1 to 9, in which the connection structure (66) is one of connection structures (66) formed in the semiconductor layer.

[Clause 11]

The semiconductor device according to clause 10, in which at least some of the connection structures (66) are equidistantly arranged parallel to each other.

[Clause 12]

The semiconductor device according to clause 10 or 11, in which
the gate interconnect (54) includes
   a first gate interconnect part (54A1) and a second gate interconnect part (54A2) extending in a first direction that is parallel to the second surface (14B), and
   a third gate interconnect part (54B1) and a fourth gate interconnect part (54B2) extending in a second direction that is orthogonal to the first direction and parallel to the second surface (14B), and
the first gate interconnect part (54A1) is connected to one end of the third gate interconnect part (54B1) and one end of the fourth gate interconnect part (54B2), and the second gate interconnect part (54A2) is connected to the other end of the third gate interconnect part (54B1) and the other end of the fourth gate interconnect part (54B2) so that the gate interconnect (54) forms a rectangular closed loop in plan view.

[Clause 13]

The semiconductor device according to clause 12, in which
each of the connection structures (66) intersects the first gate interconnect part (54A1) or the second gate interconnect part (54A2) in plan view, and
each of the gate trenches (16) intersects the third gate interconnect part (54B1) or the fourth gate interconnect part (54B2) in plan view.

[Clause 14]

The semiconductor device according to any one of clauses 11 to 13, further including:
a peripheral trench (72) formed in the second surface (14B) of the semiconductor layer (14), the peripheral trench (72) surrounding the connection structures (66) in plan view and being connected to the connection trench (68) of each of the connection structures (66),
in which the inter-source interconnects (70) of the connection structures (66) are connected to each other in the peripheral trench (72).

[Clause 15]

The semiconductor device according to any one of clauses 1 to 14, further including:
a second peripheral trench (20) formed in the second surface (14B) of the semiconductor layer (14), the second peripheral trench (20) surrounding the gate trenches (16) in plan view and being connected to each of the gate trenches (16),
in which the field plate electrodes (22) are connected to each other in the second peripheral trench (20).

[Clause 16]

The semiconductor device according to any one of clauses 1 to 15, in which the gate electrodes (24) are each connected to the gate interconnect (54) in a region in which the gate interconnect (54) intersects the gate electrodes (24) in plan view.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor layer including a first surface and a second surface opposite to the first surface;
gate trenches formed in the second surface of the semiconductor layer;
gate electrodes, each of the gate electrodes being embedded in one of the gate trenches;
field plate electrodes, each of the field plate electrodes being embedded in one of the gate trenches and insulated from the gate electrodes and including a first end and a second end;
an insulation layer formed on the second surface of the semiconductor layer;
a gate interconnect formed on the insulation layer and connected to each of the gate electrodes, the gate interconnect forming a loop in plan view;
a first source interconnect formed on the insulation layer and connected to the first end of each of the field plate electrodes, the first source interconnect disposed inside the loop of the gate interconnect in plan view;
a second source interconnect formed on the insulation layer and connected to the second end of each of the field plate electrodes, the second source interconnect disposed outside the loop of the gate interconnect in plan view; and
a connection structure formed in the semiconductor layer,
wherein the connection structure includes a connection trench formed in the second surface of the semiconductor layer and intersecting the gate interconnect in plan view and an inter-source interconnect embedded in the connection trench, and the inter-source interconnect is electrically connected to the first source interconnect and the second source interconnect.

2. The semiconductor device according to claim 1, wherein the gate interconnect forms a closed loop in plan view.

3. The semiconductor device according to claim 1, wherein the inter-source interconnect electrically connects the first source interconnect and the second source interconnect with a distance less than a distance between the first end and the second end of each of the field plate electrodes.

4. The semiconductor device according to claim 1, wherein the inter-source interconnect includes a first connecting portion connected to the first source interconnect, a second connecting portion connected to the second source interconnect, and an intermediate portion extending between the first connecting portion and the second connecting portion, the intermediate portion is equal to the first connecting portion and the second connecting portion in thickness in a direction orthogonal to the second surface of the semiconductor layer.

5. The semiconductor device according to claim 1, wherein the inter-source interconnect includes a first connecting portion connected to the first source interconnect, a second connecting portion connected to the second source interconnect, and an intermediate portion extending between the first connecting portion and the second connecting portion, the intermediate portion has a thickness that is smaller than that of the first connecting portion and the second connecting portion in a direction orthogonal to the second surface of the semiconductor layer.

6. The semiconductor device according to claim 1, wherein the connection structure further includes a conductive layer insulated from the inter-source interconnect and embedded in the connection trench.

7. The semiconductor device according to claim 6, wherein the conductive layer is at least partially disposed between the gate interconnect and the inter-source interconnect and electrically connects the first source interconnect and the second source interconnect.

8. The semiconductor device according to claim 6, wherein the conductive layer is located below the inter-source interconnect and is electrically floating.

9. The semiconductor device according to claim 6, wherein the conductive layer is at least partially disposed between the gate interconnect and the inter-source interconnect and is electrically floating.

10. The semiconductor device according to claim 1, wherein the connection structure is one of connection structures formed in the semiconductor layer.

11. The semiconductor device according to claim 10, wherein at least some of the connection structures are equidistantly arranged parallel to each other.

12. The semiconductor device according to claim 10 wherein
the gate interconnect includes
a first gate interconnect part and a second gate interconnect part extending in a first direction that is parallel to the second surface, and
a third gate interconnect part and a fourth gate interconnect part extending in a second direction that is orthogonal to the first direction and parallel to the second surface, and
the first gate interconnect part is connected to one end of the third gate interconnect part and one end of the fourth gate interconnect part, and the second gate interconnect part is connected to the other end of the third gate interconnect part and the other end of the fourth gate interconnect part so that the gate interconnect forms a rectangular closed loop in plan view.

13. The semiconductor device according to claim 12, wherein
each of the connection structures intersects the first gate interconnect part or the second gate interconnect part in plan view, and
each of the gate trenches intersects the third gate interconnect part or the fourth gate interconnect part in plan view.

14. The semiconductor device according to claim 11, further comprising:
a peripheral trench formed in the second surface of the semiconductor layer, the peripheral trench surrounding the connection structures in plan view and being connected to the connection trench of each of the connection structures,
wherein the inter-source interconnects of the connection structures are connected to each other in the peripheral trench.

15. The semiconductor device according to claim 1, further comprising:
a second peripheral trench formed in the second surface of the semiconductor layer, the second peripheral trench surrounding the gate trenches in plan view and being connected to each of the gate trenches,
wherein the field plate electrodes are connected to each other in the second peripheral trench.

16. The semiconductor device according to claim 1, wherein the gate electrodes are each connected to the gate interconnect in a region in which the gate interconnect intersects the gate electrodes in plan view.
